(19) United States
(12) Patent Application Publication
(10) Pub. No.: US 2026/0362831 A1
(43) Pub. Date: Nov. 12, 2026

(54) LIGHT RECEIVING ELEMENT AND ELECTRONIC APPARATUS

(71) Applicant: SONY SEMICONDUCTOR SOLUTIONS CORPORATION, KANAGAWA (JP)

(72) Inventors: KOJI NUNOMURA, KANAGAWA (JP); CHIHIRO ARAI, KANAGAWA (JP)

(21) Appl. No.: 19/123,075

(22) PCT Filed: Sep. 26, 2023
(86) PCT No.: PCT/JP2023/034818

§ 371 Date: Apr. 22, 2025

(30) Foreign Application Priority Data
Oct. 31, 2022 (JP) 2022-174898

(51) Int. Cl. H10F 39/00; H04N 25/618; H04N 25/778; H04N 25/79

(52) U.S. Cl. CPC H10F 39/8037; H04N 25/618; H04N 25/778; H10F 39/805; H04N 25/79

(57) ABSTRACT

[Object] A light receiving element capable of reducing random noise is provided. [Solving Means] A light receiving element according to an aspect of the present disclosure includes a photoelectric conversion circuit that photoelectrically converts incident light into a pixel signal and outputs the pixel signal, and a source follower circuit that includes an amplification transistor that amplifies the pixel signal. According to this light receiving element, an insulation film is formed immediately below each of a drain region and a source region of the amplification transistor.

### TECHNICAL FIELD

The present disclosure relates to a light receiving element and an electronic apparatus.

### BACKGROUND ART

There is a CMOS image sensor of such a type that reads pixel signals photoelectrically converted by photodiodes into source follower circuits simultaneously from all pixels. Simultaneous reading of pixel signals from all pixels, as in the manner performed by this type of CMOS image sensor, increases power consumption. Meanwhile, if amplification transistors of source follower circuits are driven in a lower current region than a conventional current region to reduce power consumption, random noise (RN) deterioration may be caused. This random noise deterioration is caused largely by an influence of thermal noise produced in the source follower circuits.

### CITATION LIST

### Patent Literature

### [PTL 1]

Japanese Patent Laid-open No. 2016-42557

### SUMMARY

### Technical Problem

Accordingly, the present disclosure provides a light receiving element and an electronic apparatus capable of reducing random noise.

### Solution to Problem

A light receiving element according to an aspect of the present disclosure includes a photoelectric conversion circuit that photoelectrically converts incident light into a pixel signal and outputs the pixel signal, and a source follower circuit that includes an amplification transistor that amplifies the pixel signal. According to this light receiving element, an insulation film is formed immediately below each of a drain region and a source region of the amplification transistor.

In addition, an impurity concentration of a semiconductor well region formed between the drain region and the source region may be a concentration at which depletion reaches a depth equivalent to each of lower ends of the drain region and the source region, or a position deeper than the lower ends during driving of the amplification transistor.

In addition, the impurity concentration may be ten times or lower than 4e17 (cm⁻³).

In addition, the semiconductor well region may be an epitaxial growth layer of silicon.

In addition, the semiconductor well region may include a silicon-germanium layer immediately below a channel region formed between the drain region and the source region during driving of the amplification transistor.

In addition, the insulation film may have a thickness larger than at least a depth of a depletion layer formed during driving of the amplification transistor.

In addition, the insulation film may have a thickness equal to or smaller than 10% of a thickness of a semiconductor substrate constituting the amplification transistor.

In addition, the insulation film may surround the amplification transistor.

In addition, a part of each of the drain region and the source region may be a polysilicon film.

In addition, the insulation film may be also formed immediately below a channel region formed between the drain region and the source region during driving of the amplification transistor.

In addition, the channel region may be formed on an Si (110) surface.

In addition, the amplification transistor may be a Fin-type MOS transistor.

In addition, the amplification transistor may be disposed on a semiconductor substrate identical to a semiconductor substrate of the photoelectric conversion circuit.

In addition, the amplification transistor may be disposed on a semiconductor substrate different from a semiconductor substrate of the photoelectric conversion circuit.

An electronic apparatus according to an aspect of the present disclosure includes a light receiving element that includes a photoelectric conversion circuit that photoelectrically converts incident light into a pixel signal and outputs the pixel signal, and a source follower circuit that includes an amplification transistor that amplifies the pixel signal. According to this electronic apparatus, an insulation film is formed immediately below each of a drain region and a source region of the amplification transistor.

### BRIEF DESCRIPTION OF DRAWINGS

FIG. 1 is a block diagram illustrating a configuration example of a CMOS image sensor according to a first embodiment.

FIG. 2 is a diagram illustrating a circuit configuration of each pixel of a pixel array unit.

FIG. 3 is a diagram illustrating an example of a laminated structure of the CMOS image sensor according to the first embodiment.

FIG. 4 is a plan diagram illustrating an example of a layout of an upper pixel array unit.

FIG. 5 is a cross-sectional diagram taken along a section line A-A illustrated in FIG. 4.

FIG. 6A is a cross-sectional diagram illustrating a step for forming a silicon oxide film on a semiconductor substrate.

FIG. 6B is a cross-sectional diagram illustrating a step for forming an insulation film within the semiconductor substrate.

FIG. 6C is a cross-sectional diagram illustrating a step for etching a part of the insulation film.

FIG. 6D is a cross-sectional diagram illustrating a selective epitaxial growth step.

FIG. 6E is a cross-sectional diagram illustrating a non-selective epitaxial growth step.

FIG. 6F is a cross-sectional diagram illustrating a flattening step.

FIG. 6G is a cross-sectional diagram illustrating a step for forming a gate electrode, a drain region, and a source region.

FIG. 7A is a cross-sectional diagram illustrating another example of the step for forming the silicon oxide film on the semiconductor substrate.

FIG. 7B is a cross-sectional diagram illustrating another example of the step for forming the insulation film within the semiconductor substrate.

FIG. 7C is a cross-sectional diagram illustrating a step for dividing the insulation film.

FIG. 7D is a cross-sectional diagram illustrating another example of the step for etching a part of the insulation film.

FIG. 7E is a cross-sectional diagram illustrating a selective epitaxial growth step.

FIG. 7F is a cross-sectional diagram illustrating a non-selective epitaxial growth step.

FIG. 7G is a cross-sectional diagram illustrating a flattening step.

FIG. 7H is a cross-sectional diagram illustrating a step for forming a gate electrode, a drain region, and a source region.

FIG. 8 is a cross-sectional diagram illustrating a structure of a first amplification transistor according to a second embodiment.

FIG. 9 is a perspective diagram illustrating a structure of a typical Fin-type MOS transistor.

FIG. 10 is a cross-sectional diagram illustrating a structure of a first amplification transistor according to a third embodiment.

FIG. 11A is a cross-sectional diagram illustrating a step for forming a semiconductor substrate.

FIG. 11B is a cross-sectional diagram illustrating a step for forming a stopper film within the semiconductor substrate.

FIG. 11C is a cross-sectional diagram illustrating a step for forming trenches for an ESS.

FIG. 11D is a cross-sectional diagram illustrating a step for forming an ESS.

FIG. 11E is a cross-sectional diagram illustrating a step for forming insulation films within the trenches and the ESS.

FIG. 11F is a cross-sectional diagram illustrating a flattening step.

FIG. 11G is a cross-sectional diagram illustrating a step for forming a gate electrode, a drain region, and a source region.

FIG. 12 is a diagram illustrating a circuit configuration of a pixel according to a first modification.

FIG. 13 is a diagram illustrating a circuit configuration of a pixel according to a second modification.

FIG. 14 is a diagram illustrating a circuit configuration of a pixel according to a third modification.

FIG. 15 is a diagram illustrating a circuit configuration of a pixel according to a fourth modification.

FIG. 16 is a plan diagram illustrating an example of a layout of a sensor chip according to a fourth modification.

FIG. 17 is a cross-sectional diagram taken along a section line B-B illustrated in FIG. 16.

FIG. 18 is a cross-sectional diagram around a transfer transistor and a first selection transistor in the layout illustrated in FIG. 16.

FIG. 19 is a cross-sectional diagram illustrating a first amplification transistor of the fourth modification to which a Fin-type MOS transistor is applied.

FIG. 20 is a plan diagram illustrating an example of a layout of a sensor chip according to a fifth modification.

FIG. 21 is a diagram illustrating a circuit configuration of a pixel according to a sixth modification.

FIG. 22 is a plan diagram illustrating an example of a layout of a sensor chip according to a sixth modification.

FIG. 23 is a plan diagram illustrating an example of a layout of a sensor chip according to a seventh modification.

FIG. 24 is a diagram illustrating a configuration of a CMOS image sensor according to a fourth embodiment.

FIG. 25 is a cross-sectional diagram illustrating a part of the CMOS image sensor according to the fourth embodiment and taken in a vertical direction.

FIG. 26 is a block diagram illustrating a configuration example of an electronic apparatus according to a fifth embodiment.

FIG. 27 is a block diagram depicting an example of schematic configuration of a vehicle control system.

FIG. 28 is a diagram of assistance in explaining an example of installation positions of an outside-vehicle information detecting section and an imaging section.

### DESCRIPTION OF EMBODIMENTS

Preferred embodiments of the present disclosure will be hereinafter described in detail with reference to the accompanying drawings. Described in the following embodiments will be an example which applies a light receiving element according to the present disclosure to a CMOS image sensor for capturing an image of a subject and outputting pixel signals of respective pixels of the image. Note that constituent elements included in the present description and the drawings and having substantially identical functional configurations will be given identical reference signs to avoid repetitive explanation.

### First Embodiment

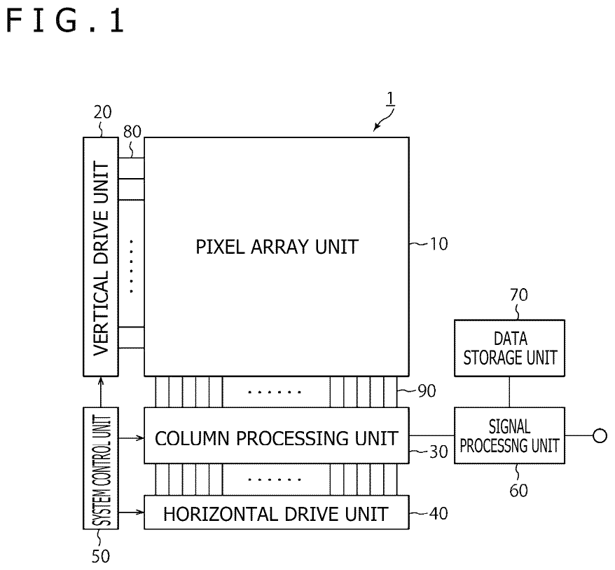

FIG. 1 is a block diagram illustrating a configuration example of a CMOS image sensor according to a first embodiment. A CMOS image sensor 1 illustrated in FIG. 1 includes a pixel array unit 10, a vertical drive unit 20, a column processing unit 30, a horizontal drive unit 40, a system control unit 50, a signal processing unit 60, and a memory unit 70.

The pixel array unit 10 includes multiple pixels two-dimensionally arranged in a matrix shape. Each of the pixels includes a photoelectric conversion element which generates charge having a charge quantity corresponding to a light amount of incident light and accumulates the generated charge inside the photoelectric conversion element. A circuit configuration of the pixels will be described below. Moreover, pixel drive lines 80 are connected with pixel rows of the pixel array unit 10 with one-to-one correspondence, and vertical signal lines 90 are connected with pixel columns of the pixel array unit 10 with one-to-one correspondence.

The vertical drive unit 20 includes a shift register, an address decoder, and others to drive the respective pixels of the pixel array unit 10 for each row or other units. One end of each of the pixel drive lines 80 is connected to the vertical drive unit 20 at an output end associated with the corresponding row of the pixel rows.

The column processing unit 30 includes signal processing circuits provided for the pixel columns of the pixel array unit 10 with one-to-one correspondence. Each of the signal processing circuits of the column processing unit 30 performs signal processing, such as noise removal processing like CDS (Correlated Double Sampling) processing, and A/D (Analog/Digital) conversion processing, for pixel signals output from the respective pixels of the selected row via the vertical signal line 90. The column processing unit 30 temporarily retains the processed pixel signals.

The horizontal drive unit 40 includes a shift register, an address decoder, and others to sequentially select the signal processing circuits of the column processing unit 30. The pixel signals processed by the respective signal processing circuits of the column processing unit 30 are sequentially output to the signal processing unit 60 by selective scanning performed by the horizontal drive unit 40.

The system control unit 50 includes a timing generator for generating various timing signals and others to control the vertical drive unit 20, the column processing unit 30, and the horizontal drive unit 40 in accordance with various timing signals generated by the timing generator.

The signal processing unit 60 has at least an adding function. The signal processing unit 60 performs various types of signal processing, such as adding, for pixel signals output from the column processing unit 30. In this case, the signal processing unit 60 stores interim results and the like of signal processing in the memory unit 70 as necessary, and refers to the stored interim results and the like at necessary timing. The signal processing unit 60 outputs the processed pixel signals.

The memory unit 70 includes a DRAM (Dynamic Random Access Memory), a SRAM (Static Random Access Memory), and others.

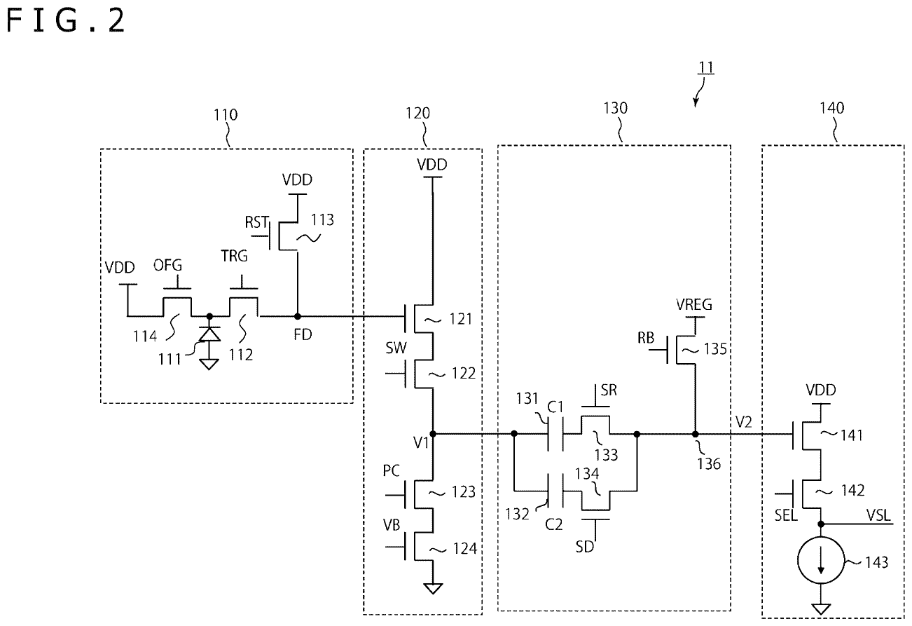

FIG. 2 is a diagram illustrating a circuit configuration of each of the pixels of the pixel array unit 10. A pixel 11 illustrated in FIG. 2 includes a photoelectric conversion circuit 110, a first source follower circuit 120, a signal retention selection circuit 130, and a second source follower circuit 140. The respective circuits will be hereinafter described.

The photoelectric conversion circuit 110 includes a photodiode 111, a transfer transistor 112, a first reset transistor 113, and a discharge transistor 114. For example, each of the transfer transistor 112, the first reset transistor 113, and the discharge transistor 114 includes an N-channel type MOS transistor.

The photodiode 111 generates charge by photoelectrically converting incident light. An anode of the photodiode 111 is connected to ground having reference potential. A cathode of the photodiode 111 is connected to the transfer transistor 112 and the discharge transistor 114.

The transfer transistor 112 transfers charge from the photodiode 111 to FD (Floating Diffusion) in accordance with a transfer signal TRG input to a gate of the transfer transistor 112 from the vertical drive unit 20 via the pixel drive line 80. The FD accumulates charge and generates a pixel signal indicating a voltage corresponding to a charge quantity. A drain of the transfer transistor 112 is connected to the cathode of the photodiode 111, while a source of the transfer transistor 112 is connected to the FD.

The first reset transistor 113 extracts charge from the FD and initializes the charge in accordance with a first reset signal RST input to a gate of the first reset transistor 113 from the vertical drive unit 20 via the pixel drive line 80. A drain of the first reset transistor 113 is connected to a power source line having potential of a power source voltage VDD, while a source of the first reset transistor 113 is connected to the FD.

The discharge transistor 114 discharges and initializes charge accumulated in the photodiode 111 in accordance with a discharge signal OFG input to a gate of the discharge transistor 114 from the vertical drive unit 20 via the pixel drive line 80. A drain of the discharge transistor 114 is connected to the cathode of the photodiode 111 and the drain of the transfer transistor 112. A source of the discharge transistor 114 is connected to the power source line described above.

The first source follower circuit 120 includes a first amplification transistor 121, a first selection transistor 122, a bias cut transistor 123, and a load transistor 124. The respective transistors are connected in series between ground and a power source line having potential of the power source voltage VDD, and each include an N-channel type MOS transistor, for example.

The first amplification transistor 121 amplifies a voltage level of a pixel signal generated by the FD into a voltage V1, and outputs the amplified pixel signal to the signal retention selection circuit 130. A gate of the first amplification transistor 121 is connected to the FD. A drain of the first amplification transistor 121 is connected to the power source line described above. A source of the first amplification transistor 121 is connected to a drain of the first selection transistor 122.

The first selection transistor 122 switches whether or not to transfer the pixel signal amplified by the first amplification transistor 121 to the signal retention selection circuit 130 in accordance with a switching signal SW input to a gate of the first selection transistor 122 from the vertical drive unit 20 via the pixel drive line 80. A drain of the first selection transistor 122 is connected to the source of the first amplification transistor 121, while a source of the first selection transistor 122 is connected to the signal retention selection circuit 130 and a drain of the bias cut transistor 123.

The bias cut transistor 123 switches whether or not to supply current from the load transistor 124 in accordance with a bias cut signal PC input to a gate of the bias cut transistor 123 from the vertical drive unit 20 via the pixel drive line 80. A source of the bias cut transistor 123 is connected to a drain of the load transistor 124.

The load transistor 124 supplies predetermined current into the first source follower circuit 120 in accordance with a bias signal VB input to a gate of the load transistor 124 from the vertical drive unit 20 via the pixel drive line 80. A source of the load transistor 124 is connected to ground.

The signal retention selection circuit 130 includes a first capacitive element 131, a second capacitive element 132, a first sampling transistor 133, a second sampling transistor 134, and a second reset transistor 135. Each of the transistors includes an N-channel type MOS transistor, for example.

One end of the first capacitive element 131 and one end of the second capacitive element 132 are connected to a common output terminal of the first source follower circuit 120 (the source of the first selection transistor 122). The other end of the first capacitive element 131 is connected to a drain of the first sampling transistor 133. The other end of the second capacitive element 132 is connected to a drain of the second sampling transistor 134.

The first sampling transistor 133 switches whether or not to output a pixel signal retained in the first capacitive element 131 to an output node 136 in accordance with a first sampling signal SR input to a gate of the first sampling transistor 133 from the vertical drive unit 20 via the pixel drive line 80. A source of the first sampling transistor 133 is connected to the output node 136.

The second sampling transistor 134 switches whether or not to output a pixel signal retained in the second capacitive element 132 to the output node 136 in accordance with a second sampling signal SD input to a gate of the second sampling transistor 134 from the vertical drive unit 20 via the pixel drive line 80. A source of the second sampling transistor 134 is also connected to the output node 136 to which the source of the first sampling transistor 133 is also connected.

The second reset transistor 135 initializes a voltage V2 of the output node 136 into a predetermined voltage VREG in accordance with a second reset signal RB input to a gate of the second reset transistor 135 from the vertical drive unit 20 via the pixel drive line 80. The voltage VREG is set to potential lower than the power source voltage VDD. A drain of the second reset transistor 135 is connected to a voltage wire having potential of the voltage VREG, while a source of the second reset transistor 135 is connected to the output node 136.

The second source follower circuit 140 is a circuit which selectively reads a signal from the signal retention selection circuit 130 and amplifies the read signal, and includes a second amplification transistor 141, a second selection transistor 142, and a current source 143. For example, each of the second amplification transistor 141 and the second selection transistor 142 connected in series to each other includes an N-channel type MOS transistor.

A gate of the second amplification transistor 141 is connected to the output node 136 of the signal retention selection circuit 130. Moreover, a drain of the second amplification transistor 141 is connected to a power source line having potential of the power source voltage VDD. Furthermore, a source of the second amplification transistor 141 is connected to a drain of the second selection transistor 142.

The second selection transistor 142 switches whether or not to output a pixel signal amplified by the second amplification transistor 141 to a signal line VSL in accordance with a second selection signal SEL input to a gate of the second selection transistor 142 from the vertical drive unit 20 via the pixel drive line 80. A source of the second selection transistor 142 is connected to a signal line VSI and the current source 143.

The current source 143 is connected in series to the second selection transistor 142. The current source 143 supplies fixed current to the second amplification transistor 141 and the second selection transistor 142 in accordance with a control signal input to a gate of the current source 143 from the vertical drive unit 20 via the pixel drive line 80.

According to the CMOS image sensor 1 configured as described above, the vertical drive unit 20 supplies the first reset signal RST and the transfer signal TRG, both as high-level signals, to all the pixels 11 at a start of exposure. As a result, the photodiodes 111 are initialized.

Subsequently, the vertical drive unit 20 supplies the high-level first reset signal RST to all the pixels 11 throughout a pulse period immediately before an end of exposure while maintaining the second reset signal RB and the first sampling signal SR at the high level. As a result, the FD is initialized, and a pixel signal corresponding to a voltage level of the FD at that time is retained in each of the first capacitive elements 131.

Thereafter, the vertical drive unit 20 supplies the high-level transfer signal TRG to all the pixels 11 throughout a pulse period at an end of exposure while maintaining the second reset signal RB and the second sampling signal SD at the high level. As a result, signal charge corresponding to an exposure quantity is transferred to the FD, and a pixel signal corresponding to a level of the FD at that time is retained in each of the second capacitive elements 132.

This manner of exposure control for simultaneously starting and ending exposure for all the pixels 11 is called a global shutter system. This exposure control causes each of the photoelectric conversion circuits 110 of all the pixels 11 to sequentially generate reset-level and data-level pixel signals. The reset-level pixel signal is retained in each of the first capacitive elements 131, while the data-level pixel signal is retained in each of the second capacitive elements 132.

After the end of exposure, the vertical drive unit 20 sequentially selects the row and sequentially outputs the reset-level and data-level pixel signals of the selected row. At the time of output of the reset-level pixel signal, the vertical drive unit 20 supplies the high-level first sampling signal SR throughout a predetermined period while maintaining the first reset signal RST and the second selection signal SEL of the selected row at the high level. As a result, the first capacitive element 131 is connected to the output node 136, and the reset level is read out.

After the readout of the reset level, the vertical drive unit 20 supplies the high-level second reset signal RB throughout a pulse period while maintaining the first reset signal RST and the second selection signal SEL of the selected row at the high level. As a result, the voltage level of the output node 136 is initialized. At this time, the first sampling transistor 133 and the second sampling transistor 134 are both in an off-state. Accordingly, the first capacitive element 131 and the second capacitive element 132 are cut from the output node 136.

After the initialization of the output node 136, the vertical drive unit 20 supplies the high-level second sampling signal SD throughout a predetermined period while maintaining the first reset signal RST and the second selection signal SEL of the selected row at the high level. As a result, the second capacitive element 132 is connected to the output node 136, and a data-level pixel signal is read out.

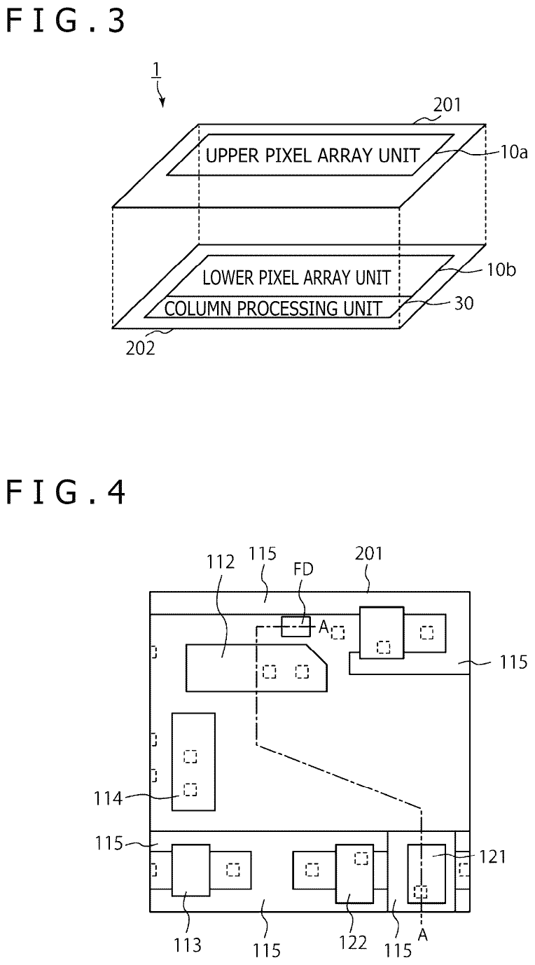

FIG. 3 is a diagram illustrating an example of a laminated structure of the CMOS image sensor 1 according to the first embodiment. The CMOS image sensor 1 according to the present embodiment includes a sensor chip 201 (first chip), and a logic chip 202 (second chip) laminated below the sensor chip 201. For example, the sensor chip 201 and the logic chip 202 are electrically connected by what is called Cu—Cu bonding for bonding between Cu pads formed on the respective chips. Note that these chips can be connected by vias or bumps as well as Cu—Cu bonding.

An upper pixel array unit 10a is disposed on the sensor chip 201. A lower pixel array unit 10b and the column processing unit 30 are disposed on the logic chip 202. A part of each of the pixels 11 included in the pixel array unit 10 is disposed on the upper pixel array unit 10a, while the remaining part is disposed on the lower pixel array unit 10b. For example, the photoelectric conversion circuit 110 and the first amplification transistor 121 and the first selection transistor 122 of the first source follower circuit 120 are disposed on the upper pixel array unit 10a. In this case, the bias cut transistor 123 and the load transistor 124 of the first source follower circuit 120, the signal retention selection circuit 130, and the second source follower circuit 140 are disposed on the lower pixel array unit 10b.

Note that the layout of the sensor chip 201 and the logic chip 202 is not limited to the layout described above. For example, all the elements included in the first source follower circuit 120 may be disposed on the logic chip 202. In other words, the first source follower circuit 120 may be formed on a semiconductor substrate different from the semiconductor substrate where the photoelectric conversion circuit 110 is formed. In this case, the sensor chip 201 has a wider space for arranging the photodiodes 111. Accordingly, sensitivity improves.

In addition, the vertical drive unit 20, the horizontal drive unit 40, the system control unit 50, the signal processing unit 60, and the memory unit 70 are also disposed on the logic chip 202 in addition to the column processing unit 30. However, these units are not illustrated in FIG. 3.

FIG. 4 is a plan diagram illustrating an example of the layout of the upper pixel array unit 10a. As illustrated in FIG. 4, an insulation film 115 on the upper pixel array unit 10a is formed at a boundary between an area where the FD, the transfer transistor 112, and the discharge transistor 114 are disposed and an area where the first reset transistor 113 is disposed. The insulation film 115 is an element separation film formed as STI (Shallow Trench Isolation).

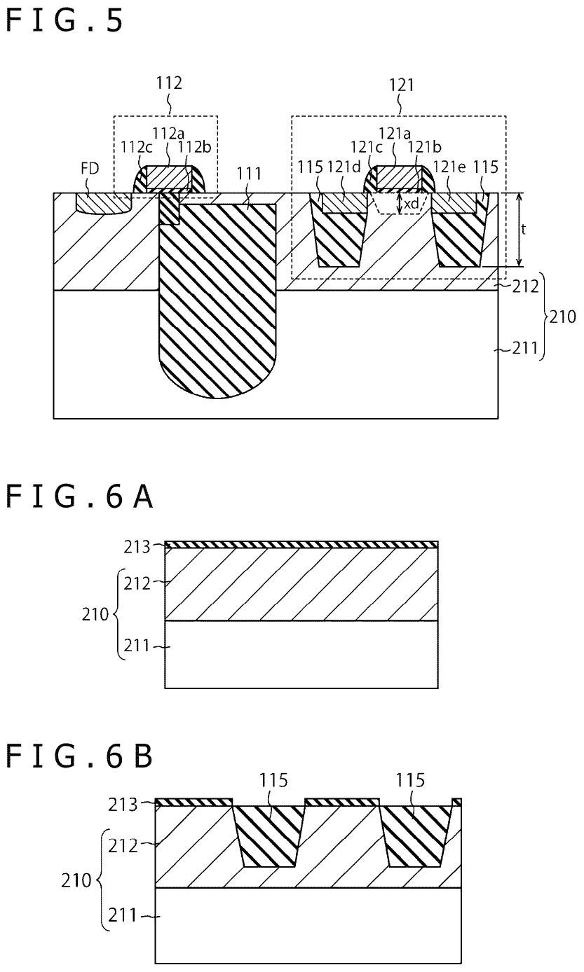

Moreover, the insulation film 115 is also formed at a boundary portion between the area where the first reset transistor 113 is disposed and an area where the first selection transistor 122 is disposed. Furthermore, the insulation film 115 is also formed at a boundary between the area where the first selection transistor 122 is disposed and an area where the first amplification transistor 121 is disposed. Particularly, the insulation film 115 formed thereat is so provided as to surround the first amplification transistor 121. A cross-sectional structure of a part of the sensor chip 201 will be described herein with reference to FIG. 5.

FIG. 5 is a cross-sectional diagram taken along a section line A-A illustrated in FIG. 4. As illustrated in FIG. 5, the sensor chip 201 includes a semiconductor substrate 210. The semiconductor substrate 210 includes an N-type base layer 211, and a P-type epitaxial growth layer 212 formed on the base layer 211.

A gate insulation film 112b of the transfer transistor 112 is formed on the epitaxial growth layer 212. A gate electrode 112a of the transfer transistor 112 is formed on the gate insulation film 112b. A sidewall insulation film 112c is formed on a side surface of the gate electrode 112a. For example, the gate electrode 112a can be formed using polysilicon. Moreover, for example, each of the gate insulation film 112b and the sidewall insulation film 112c can be formed using silicon oxide (SiO₂). FD is formed in a drain region of the transfer transistor 112. Moreover, the photodiode 111 is formed in a source region of the transfer transistor 112.

Furthermore, a gate insulation film 121b of the first amplification transistor 121 is also formed on the epitaxial growth layer 212. A gate electrode 121a of the first amplification transistor 121 is formed on the gate insulation film 121b. A sidewall insulation film 121c is formed on a side surface of the gate electrode 121a. For example, the gate electrode 121a can be formed using polysilicon. Moreover, for example, each of the gate insulation film 121b and the sidewall insulation film 121c can be formed using silicon oxide (SiO₂).

A drain region 121d and a source region 121e of the first amplification transistor 121 are formed within the epitaxial growth layer 212. The insulation film 115 is formed immediately below each of the drain region 121d and the source region 121e.

As described above, the CMOS image sensor 1 according to the present embodiment includes two types of source follower circuits, i.e., the first source follower circuit 120 and the second source follower circuit 140. Accordingly, power consumption tends to increase. If the respective transistors of the respective source follower circuits are driven in an nA-order current region lower than a conventional uA-order current region to reduce this power consumption, random noise deterioration may be caused. This random noise deterioration is particularly caused largely by an influence of thermal noise produced in the first source follower circuit 120.

Noise V_{NSH} (V/sqrtHz) of an ordinary source follower circuit can be expressed by the following Formula (1).

$$\begin{matrix}[ Math . 1 ] & \\ {V}_{NSH} = \sqrt{\frac{4 KT}{{ℊ}_{m 1}}} ( {γ}_{n 1} + {γ}_{n 2} \frac{{ℊ}_{m 2}}{{ℊ}_{m 1}} ) \times \frac{{ℊ}_{m 1}}{C} \times \frac{π}{2} & ( 1 )\end{matrix}$$

The signs in the formula are defined as follows.
K: Boltzmann constant (=1.38×10⁻²³ J/K)
C: entire capacitance of V1 node (F)
γₙ₁: non-dimensional parameter called noise factor and dependent on bias
γₙ₂: non-dimensional parameter called noise factor and dependent on bias

As apparent from the following Formula (2), thermal noise V²_{NSH} of the first source follower circuit 120 is determined by a ratio of gm1 of the first amplification transistor 121 to gm2 of the load transistor 124 on the basis of Formula (1) described above.

$$\begin{matrix}[ Math . 2 ] & \\ {V}_{NSH}^{2} ∝ \frac{{g}_{m 2}}{{g}_{m 1}} & ( 2 )\end{matrix}$$

Note herein that gm1 and gm2 are defined by the following Formula (3).

$$\begin{matrix}[ Math . 3 ] & \\ {ℊ}_{m} = \frac{\partial {I}_{ds}}{\partial {V}_{ℊ}} & ( 3 )\end{matrix}$$

As apparent from Formula (3), each of gm1 and gm2 is an electric characteristic which indicates a level of current Ids allowed to flow between a drain and a source for each of respective gate voltages Vg of the first amplification transistor 121 and the load transistor 124. According to the present embodiment, the thermal noise V²_{NSH} is improved by enhancing gm1 of the first amplification transistor 121.

For the first amplification transistor 121, a relation expressed by the following Formula (4) holds between gm1, capacitance C_{Dep} of a depletion layer formed between the drain region 121d and the source region 121e, and capacitance Cₒₓ of the gate insulation film 121b.

$$\begin{matrix}[ Math . 4 ] & \\ {g}_{mn} ∝ {( 1 + \frac{{C}_{Dep}}{{C}_{ox}} )}^{- 1} & ( 4 )\end{matrix}$$

The current Ids between the drain and the source of the first amplification transistor 121 can be expressed by the following Formulae (5) and (6) when a current formula of Taur-Ning is applied to a subthreshold region.

$$\begin{matrix}[ Math . 5 ] & \\ {I}_{ds} = {µ}_{eff} \frac{W}{L} \sqrt{\frac{{ε}_{Si} {qN}_{a}}{4 {ψ}_{B}}} \cdot {( \frac{kT}{q} )}^{2} \cdot {e}^{q ( {V}_{ℊ} - {V}_{t} ) / mkT} \cdot ( 1 - {e}^{- {qV}_{ds} / kT} ) & ( 5 )\end{matrix}$$

$$\begin{matrix}[ Math . 6 ] & \\ {I}_{ds} = {µ}_{eff} {C}_{ox} \frac{W}{L} \cdot ( m - 1 ) \cdot {( \frac{kT}{q} )}^{2} \cdot {e}^{q ( {V}_{ℊ} - {V}_{t} ) / mkT} \cdot ( 1 - {e}^{- {qV}_{ds} / kT} ) & ( 6 )\end{matrix}$$

The signs in the formula are defined as follows.
μ_{eff}: effective mobility [cm²/V·S]
W: channel width [cm]
L: channel length [cm]
εₛᵢ: permittivity of silicon
q: elementary charge quantity
Na: accepter density (cm⁻³)
ψ_{B}: difference between Fermi potential and true potential [V]
k: Boltzmann constant
T: absolute temperature [K]
Vg: gate voltage [V]
Vt: threshold voltage [V] based on definition of 2ψ_{B}
m: body effect coefficient of MOSFET
Vds: source-drain voltage [V]

Note herein that gm calculated in accordance with the definition can be expressed by the following Formula (7).

$$\begin{matrix}[ Math . 7 ] & \\ \begin{matrix}{ℊ}_{m} = \frac{\partial {I}_{ds}}{\partial {V}_{ℊ}} \\ = \frac{q}{mkT} \cdot β \cdot ( m - 1 ) \cdot {( \frac{kT}{q} )}^{2} \cdot {e}^{q ( {V}_{ℊ} - {V}_{t} ) / mkT} \cdot ( 1 - {e}^{- {qV}_{ds} / kT} ) \\ = \frac{q}{mkT} \cdot {I}_{ds}\end{matrix} & ( 7 )\end{matrix}$$

In Formula (7), the body effect coefficient m can be expressed by the following Formula (8).

$$\begin{matrix}[ Math . 8 ] & \\ \begin{matrix}m = 1 = \frac{1}{{C}_{ox}} \sqrt{\frac{{ε}_{Si} {qN}_{a}}{4 {ψ}_{B}}} \\ 1 + \frac{{C}_{dm}}{{C}_{ox}} \\ 1 + \frac{3 {t}_{ox}}{{W}_{dm}}\end{matrix} & ( 8 )\end{matrix}$$

By substituting Formula (8) described above into Formula (7) described above, the relation of Formula (4) described above can be derived. As apparent from Formula (4), gm1 improves when the capacitance C_{Dep} of the depletion layer of the first amplification transistor 121 is lowered. A relation expressed by the following Formula (9) holds between the capacitance C_{Dep}, the permittivity εₛᵢ of silicon, and the width xd which is a length of the depletion layer in a depth direction (see FIG. 5).

$$\begin{matrix}[ Math . 9 ] & \\ {C}_{Dep} ∝ \frac{{ε}_{Si}}{{x}_{d}} & ( 9 )\end{matrix}$$

As apparent from Formula (9), the capacitance C_{Dep} of the depletion layer is allowed to decrease according to an increase in the width xd of the depletion layer. The width xd herein can be expressed by the following Formula (10).

$$\begin{matrix}[ Math . 10 ] & \\ xd = \sqrt{\frac{2 {ε}_{Si} {ε}_{0} \cdot 2 {ϕ}_{B}}{{qN}_{A}}} & ( 10 )\end{matrix}$$

The signs in the formula are defined as follows.
ε₀: permittivity of vacuum
φ_{B}: surface potential
q: elementary charge quantity
N_{A}: impurity concentration of semiconductor well region

As apparent from Formula (10), the width of the depletion layer of the first amplification transistor 121 can be increased according to a decrease in the impurity concentration N_{A} of the semiconductor well region located between the drain region 121d and the source region 121e in the epitaxial growth layer 212.

However, a simple decrease in the impurity concentration N_{A} of the semiconductor well region widens not only the depletion layer of the channel region immediately below the gate insulation film 121b, but also the depletion layers immediately below the drain region 121d and the source region 121e. As a result, a short channel effect thus caused deteriorates the electric performance of the first amplification transistor 121.

According to the present embodiment, therefore, the insulation films 115 are formed immediately below the drain region 121d and the source region 121e. In such a manner, even by a decrease in the impurity concentration N_{A} of the semiconductor well region, the width xd of the depletion layer is allowed to increase while the short channel effect is reduced.

According to a conventional amplification transistor which does not have insulation films immediately below a drain region and a source region, in a case where this amplification transistor is driven in conditions where the impurity concentration N_{A} of a semiconductor well region is 4e¹⁷ (cm⁻³) and the gate voltage Vg, the drain voltage Vd, and the source voltage Vs are set to 2.9 V, 2.9 V, and 1.8 V, respectively, for example, the assumed width xd of the depletion layer is approximately 93 nm. As a result, the capacitance C_{Dep} of the depletion layer becomes approximately 1.97 (fF/μm²).

Meanwhile, in a case where the first amplification transistor 121 of the present embodiment is driven in conditions where the impurity concentration N_{A} of the semiconductor well region is 1e¹⁶ (cm⁻³), which is ten times or lower than 4e¹⁷ (cm⁻³), and the same voltages as presented above are set, the assumed width xd of the depletion layer is approximately 565 nm. As a result, the capacitance C_{Dep} of the depletion layer is approximately 0.18 (fF/μm²). To match with this increase in the width xd of the depletion layer, it is preferable that a thickness t of the insulation films 115 from the surface of the epitaxial growth layer 212 (see FIG. 5) be 10% or lower of the thickness of the semiconductor substrate 210. For example, in a case where the thickness of the semiconductor substrate 210 is approximately 6 μm, the thickness t of the insulation films 115 is approximately 510 nm.

Note that the value of the impurity concentration N_{A} and the value of the thickness t of the insulation films 115 described above are presented only by way of example. Both of the values are not limited to the specific examples described above. It is only required that the impurity concentration N_{A} be a concentration sufficient for causing depletion reaching a depth equivalent to each of lower ends of the drain region 121d and the source region 121e, or a position deeper than these lower ends during driving of the first amplification transistor 121. Moreover, it is only required that the insulation films 115 be so formed as to have the thickness t larger than at least the depth of the depletion layer formed during driving of the first amplification transistor 121.

Moreover, the impurity concentration of the semiconductor well region of the first amplification transistor 121 may be different from those concentrations of the other pixel transistors such as the transfer transistor 112 and the first reset transistor 113. Specifically, only the impurity concentration of the first amplification transistor 121 may be lower than each of the impurity concentrations of the other pixel transistors.

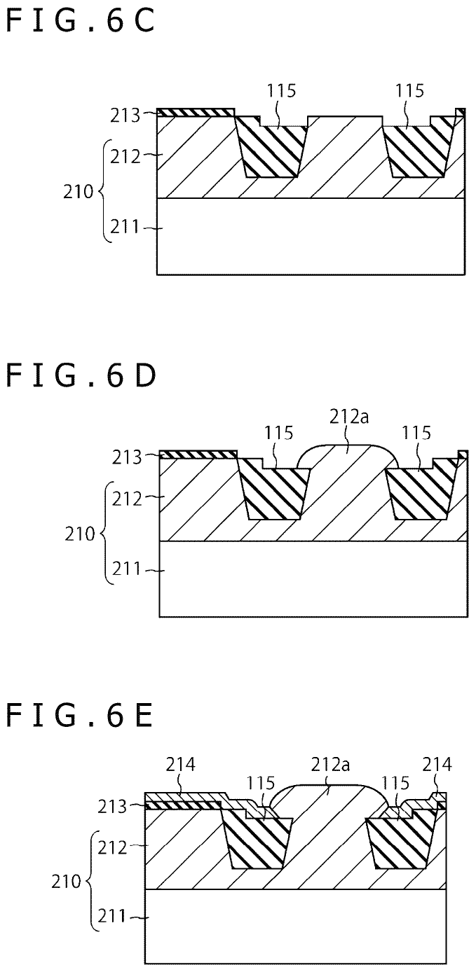

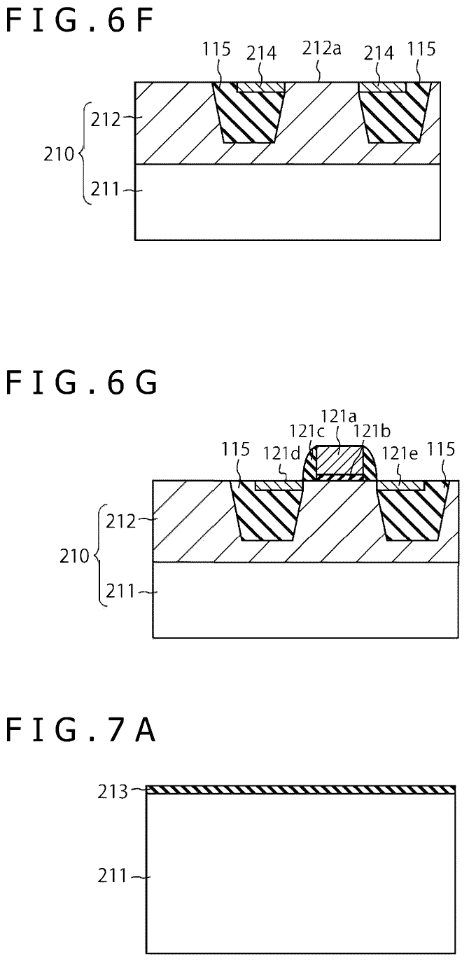

Hereinafter described with reference to FIGS. 6A to 6G will be an example of a manufacturing method of the first amplification transistor 121 according to the present embodiment.

First, as illustrated in FIG. 6A, a silicon oxide film 213 is formed on an epitaxial growth layer 212 of the semiconductor substrate 210. For example, the silicon oxide film 213 can be formed by a film forming method usually employed, such as thermal oxidation.

Subsequently, as illustrated in FIG. 6B, the insulation films 115 are formed within the epitaxial growth layer 212. For example, the insulation films 115 can be formed by embedding silicon oxide into holes opened by etching a part of the epitaxial growth layer 212. Note that this silicon oxide may be embedded using an ALD (Atomic Layer Deposition) method, for example.

Subsequently, as illustrated in FIG. 6C, a part of each of the insulation films 115 is etched using a mask or the like, for example. The portions to be etched are regions where the drain region 121d and the source region 121e of the first amplification transistor 121 will be formed.

Subsequently, as illustrated in FIG. 6D, a channel region 212a of the first amplification transistor 121 is formed by selectively developing epitaxial growth of the epitaxial growth layer 212 between the insulation films 115. In this step, epitaxial growth of the epitaxial growth layer 212 is selectively developed by using a thermal CVD (Chemical Vapor Deposition Method) system using single wafer processing, for example. In this thermal CVD system, nucleation is controlled by an effect of an etchant gas such as hydrogen chloride (HCL), for example. At this time, epitaxial growth is developed at a film forming speed sufficient for increasing a difference in film forming time from the film forming time of the silicon oxide film 213 so as to form the channel region 212a only in the region of the exposed epitaxial growth layer 212 between the insulation films 115.

Subsequently, as illustrated in FIG. 6E, a polysilicon film 214 is formed on the silicon oxide film 213 by non-selective epitaxial growth, and also the epitaxial growth of the channel region 212a is further developed. Also in this step, epitaxial growth is also developed by the thermal CVD (Chemical Vapor Deposition Method) system using single wafer processing. However, an etchant gas used in this non-selective epitaxial growth step is different from the etchant gas used in the selective epitaxial growth step described above. In other words, such an etchant gas which does not decrease nucleation is employed. Moreover, in this non-selective epitaxial growth step, epitaxial growth is developed at a film forming speed for decreasing a difference in film forming time between the silicon oxide film 213 and the channel region 212a. Furthermore, a film forming temperature (substrate temperature) in this non-selective epitaxial growth step is set to a temperature higher than a film forming temperature (substrate temperature) of the selective epitaxial growth step described above.

Subsequently, as illustrated in FIG. 6F, a flattening process is performed by CMP (Chemical Mechanical Polishing). In such a manner, the silicon oxide film 213, a part of the polysilicon film 214, and a part of the channel region 212a are removed. As a result, the polysilicon film 214 remains in a region which will become the drain region 121d and the source region 121e on the silicon oxide film 213, and the channel region 212a remains between the remaining portions of the polysilicon film 214.

Finally, as illustrated in FIG. 6G, a gate insulation film 121b, a gate electrode 121a, and a sidewall insulation film 121c are formed on the channel region 212a. Note that these components can be formed by a manufacturing process usually adopted, and therefore will not be described in detail. Moreover, in this step, an N-type impurity is injected into the polysilicon film 214 remaining after the flattening process described above, to form the drain region 121d and the source region 121e. For example, this impurity has a concentration of approximately 1e²⁰ cm⁻³. Note that the impurity need not be diffused in the entire regions of the drain region 121d and the source region 121e. It is only required that at least a portion in contact with the channel region 212a be a diffusion film. In other words, the inside of the drain region 121d and the source region 121e may be a diffusion film, while the outside thereof may be a polysilicon film. Note that a P-type semiconductor well region containing the channel region 212a has an extremely low concentration in the present embodiment. Accordingly, this semiconductor well region is a non-doped type region formed not by ion implantation but by epitaxial growth.

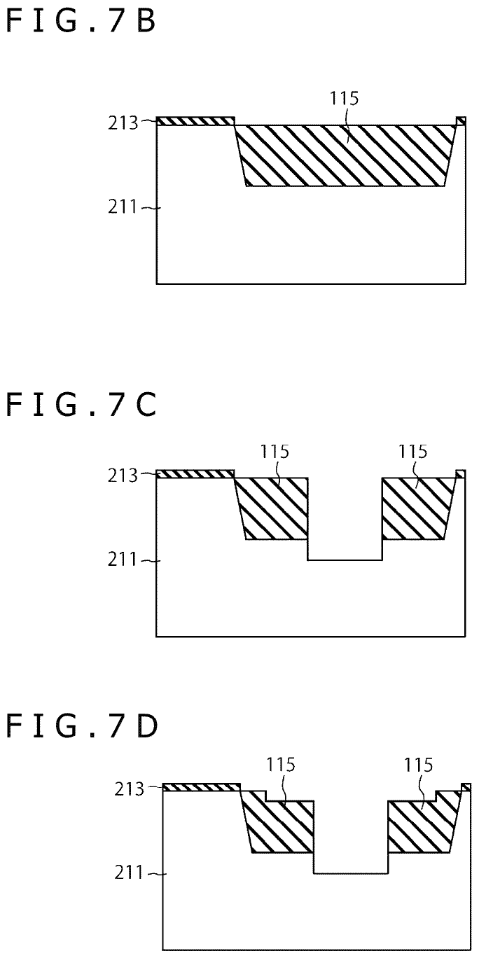

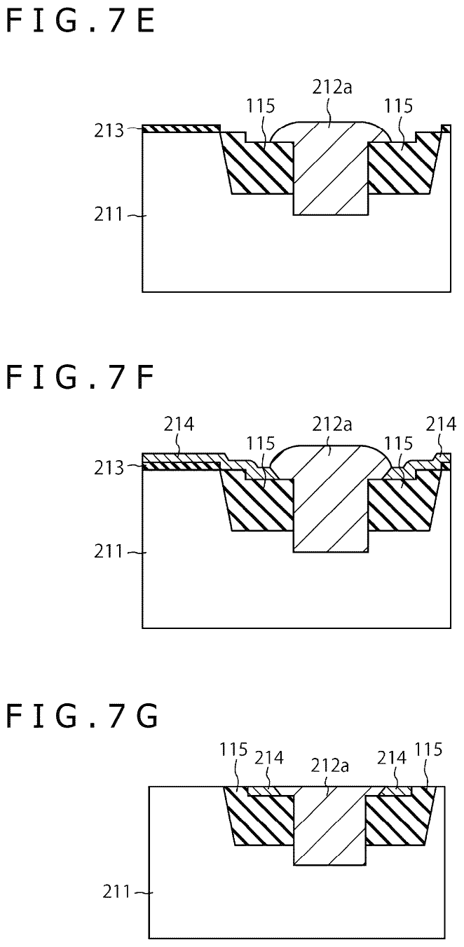

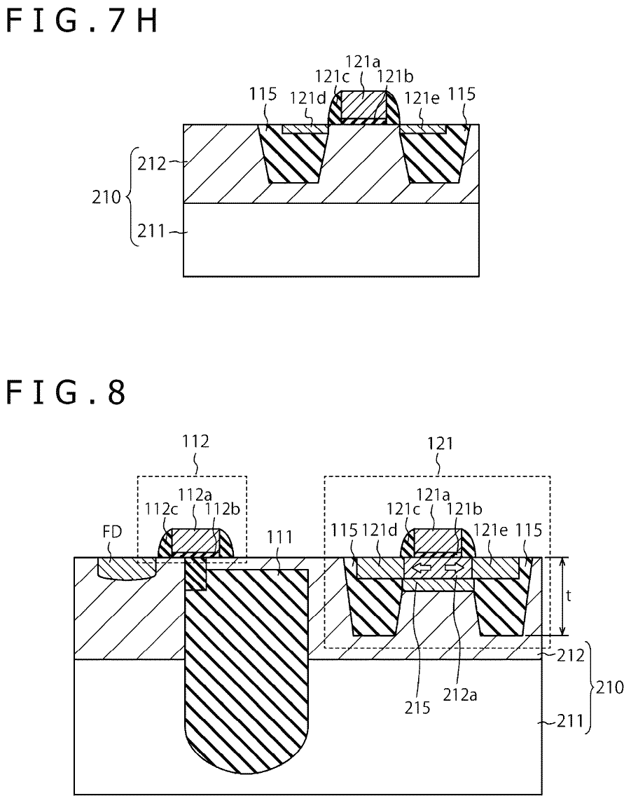

The manufacturing method of the first amplification transistor 121 is not limited to the method presented above only by way of example. Described herein with reference to FIGS. 7A to 7H will be another example of the manufacturing method of the first amplification transistor 121 according to the present embodiment. Note that the manufacturing steps included in this example and similar to the corresponding manufacturing steps described with reference to FIGS. 6A to 6G will not be repeatedly explained.

In this example, as illustrated in FIG. 7A, the silicon oxide film 213 is formed on a base layer 211 of the semiconductor substrate 210.

Subsequently, the insulation film 115 is formed as illustrated in FIG. 7B. For example, the insulation film 115 can be formed by embedding silicon oxide with use of an ALD method or the like into a hole opened by etching a part of the base layer 211. According to the example described above, the insulation film 115 is formed in a region where the drain region 121d and the source region 121e of the first amplification transistor 121 will be formed as illustrated in FIG. 6B. Meanwhile, the insulation film 115 in this example is formed in the entire region where the first amplification transistor 121 is to be formed.

Subsequently, the insulation film 115 is divided as illustrated in FIG. 7C. The division portion is a portion which will become the channel region 212a of the first amplification transistor 121. For example, the insulation film 115 can be divided by etching using an RIE (Reactive Ion Etching) device or the like.

Subsequently, as illustrated in FIG. 7D, a part of each of the insulation films 115 is etched using a mask or the like, for example. The portions to be etched are regions where the drain region 121d and the source region 121e of the first amplification transistor 121 are to be formed.

Subsequently, as illustrated in FIG. 7E, the channel region 212a, which is a P-type epitaxial growth layer, is formed by selectively developing epitaxial growth on the etched portions of the insulation films 115.

Subsequently, as illustrated in FIG. 7F, the polysilicon film 214 is formed on the silicon oxide film 213 by non-selective epitaxial growth, and also the epitaxial growth of the channel region 212a is further developed.

Subsequently, as illustrated in FIG. 7G, a flattening process is performed by CMP. In such a manner, the silicon oxide film 213, a part of the polysilicon film 214, and a part of the channel region 212a are removed. As a result, the polysilicon film 214 remains in a region which will become the drain region 121d and the source region 121e on the silicon oxide film 213, and the channel region 212a remains between the remaining portions of the polysilicon film 214.

Finally, as illustrated in FIG. 7H, the epitaxial growth layer 212 is formed on the upper side of the base layer 211, and the gate insulation film 121b, the gate electrode 121a, and the sidewall insulation film 121c are also formed on the channel region 212a. Moreover, in this step, an N-type impurity is injected into the polysilicon film 214 remaining after the flattening described above, to further form the drain region 121d and the source region 121e. For example, this impurity has a concentration of approximately 1e²⁰ cm⁻³. Note that the impurity need not be diffused in the entire regions of the drain region 121d and the source region 121e. It is only required that at least a portion in contact with the channel region 212a be a diffusion film. In other words, the inside of the drain region 121d and the source region 121e may be a diffusion film, while the outside thereof may be a polysilicon film. Note that the P-type semiconductor well region containing the channel region 212a has an extremely low concentration also in this example. Accordingly, this semiconductor well region is a non-doped type region formed not by ion implantation but by epitaxial growth.

According to the present embodiment described above, the insulation films 115 are formed immediately below the drain region 121d and the source region 121e of the first amplification transistor 121. Accordingly, the impurity concentration of the P-type semiconductor well region (channel region 212a) between the drain region 121d and the source region 121e can be lowered while the short channel effect is reduced. In such a manner, an increase in thermal noise of the first source follower circuit 120 can be reduced even when the first amplification transistor 121 is driven by low current. Therefore, the CMOS image sensor 1 according to the present embodiment can decrease random noise while reducing power consumption.

### Second Embodiment

A second embodiment will be hereinafter described. A CMOS image sensor according to the present embodiment is different from the CMOS image sensor of the first embodiment in the structure of the first amplification transistor 121.

Accordingly, described herein will be only the structure of the first amplification transistor 121, and other points will not be touched upon.

FIG. 8 is a cross-sectional diagram illustrating a structure of the first amplification transistor 121 according to the second embodiment. In FIG. 8, the constituent elements similar to the corresponding constituent elements of the first embodiment are given identical reference signs. According to the first amplification transistor 121 of the present embodiment, an SiGe (silicon-germanium) layer 215 is formed immediately below the channel region 212a. Specifically, the epitaxial growth layer 212 of the first amplification transistor 121 has a three-layer structure constituted by a first silicon layer forming the channel region 212a, the SiGe layer 215, and a second silicon layer laminated on the SiGe layer 215.

The SiGe layer 215 can be formed during the selective epitaxial growth step illustrated in FIG. 6D or FIG. 7E. In this step, for example, an etchant gas introduced into a thermal CVD device is switched from a first etchant gas for forming the SiGe layer 215 within a film forming device to a second etchant gas for forming the channel region 212a. In such a manner, the SiGe layer 215 and the channel region 212a can be selectively formed between the insulation films 115.

A distance between atoms in the SiGe layer 215 formed in the manner described above is larger than a distance between atoms of silicon in the channel region 212a. Accordingly, tensile stress is generated in a channel length direction within the channel region 212a (see arrows in FIG. 8). In this case, electron mobility within the channel region 212a improves, and therefore gm1 of the first amplification transistor 121 increases. As a result, thermal noise V²_{NSH} of the first source follower circuit 120 can be further reduced as apparent from Formula (1) explained in the first embodiment. Accordingly, further reduction of random noise is achievable in the present embodiment.

### Third Embodiment

A third embodiment will be hereinafter described. A CMOS image sensor according to the present embodiment is different from the CMOS image sensor of the first embodiment in the structure of the first amplification transistor 121.

Accordingly, similarly to the above, described herein will be only the structure of the first amplification transistor 121, and other points will not be touched upon.

In a case where the first amplification transistor 121 is disposed on an Si (111) surface, a crystal surface of the channel region 212a is disposed on the Si (111) surface which contains relatively many defects. In this case, deterioration of electric characteristics may be caused.

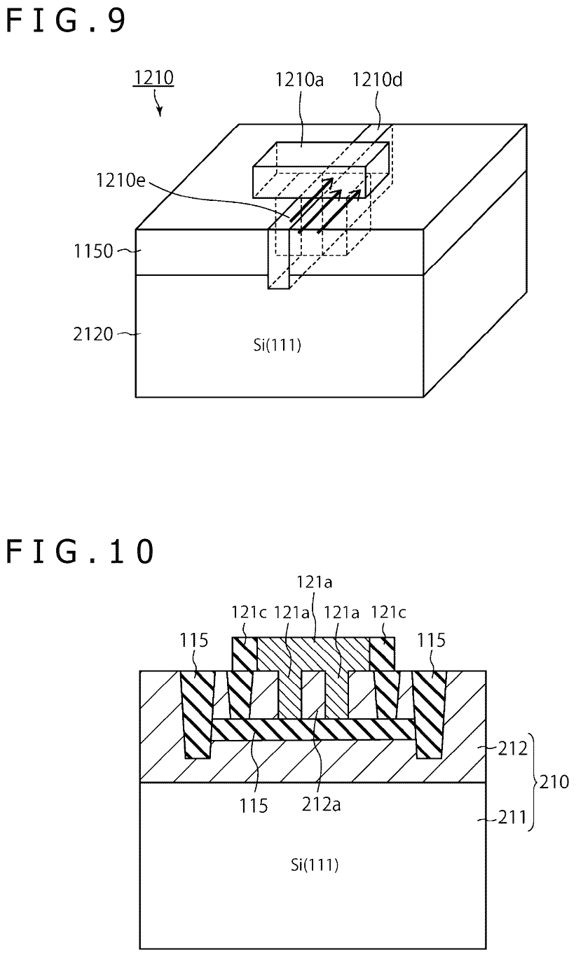

According to the present embodiment, therefore, a structure of a Fin-type MOS transistor is applied to the first amplification transistor 121. First, a structure of a typical Fin-type MOS transistor will be described herein with reference to FIG. 9.

FIG. 9 is a perspective diagram illustrating a structure of a typical Fin-type MOS transistor. According to a Fin-type MOS transistor 1210 illustrated in FIG. 9, a silicon oxide film 1150 is formed on a silicon substrate 2120. A gate electrode 1210a having what is called a double gate structure is provided within the silicon oxide film 1150. Moreover, a drain region 1210d and a source region 1210e are arranged within the silicon oxide film 1150 in such positions as to face each other via the gate electrode 1210a.

According to the Fin-type MOS transistor 1210 having the above structure, a channel region is formed on an Si (110) surface containing fewer defects than the Si (111) surface when driving voltage is applied to the gate electrode 1210a. Accordingly, deterioration of electrical characteristics is avoidable.

Subsequently to the Fin-type MOS transistor 1210 described above, a structure of the first amplification transistor 121 according to the present embodiment will be explained.

FIG. 10 is a cross-sectional diagram illustrating a structure of the first amplification transistor 121 according to a third embodiment. Note that FIG. 10 is a cross-sectional diagram and therefore does not illustrate the drain region 121d and the source region 121e. However, similarly to the Fin-type MOS transistor 1210, the drain region 121d is formed behind the gate electrode 121a, while the source region 121e is formed before the gate electrode 121a. Moreover, the insulation films 115 are formed immediately below the drain region 121d and the source region 121e similarly to the different embodiment described above.

The channel region 212a is formed on the Si (110) surface in the first amplification transistor 121 configured as above when driving voltage is applied to the gate electrode 1210a. Accordingly, deterioration of electrical characteristics is avoidable. Moreover, the insulation films 115 are formed immediately below the drain region 121d and the source region 121e. Accordingly, widening of the depletion layer can be reduced.

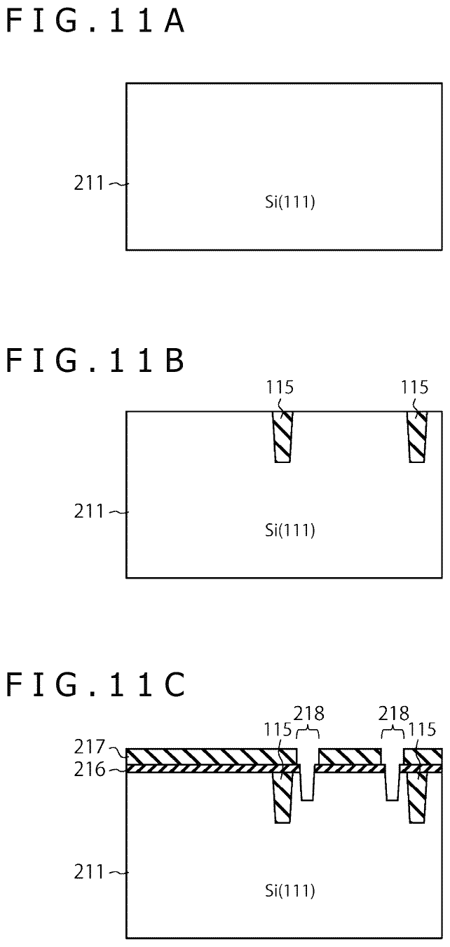

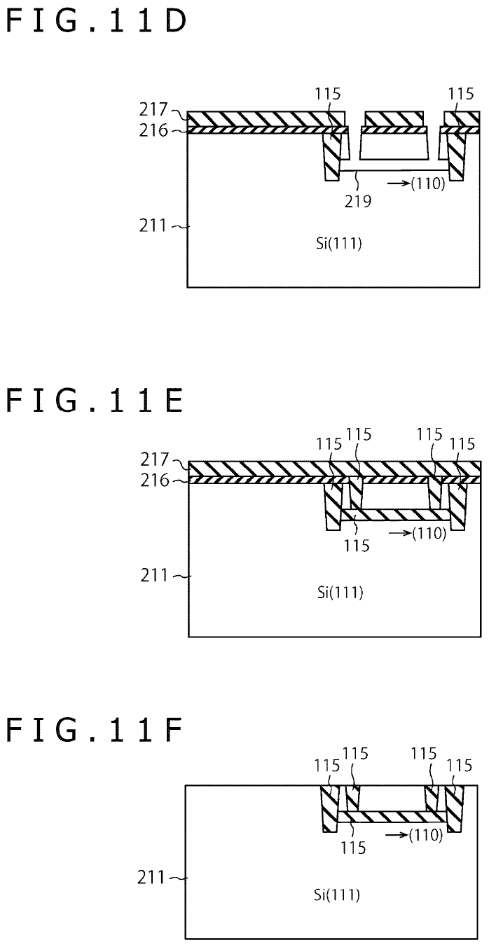

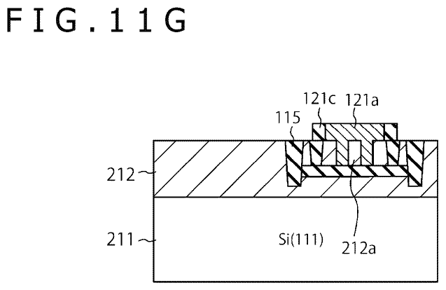

Hereinafter described with reference to FIGS. 11A to 11G will be an example of a manufacturing method of the first amplification transistor 121 according to the present embodiment.

As illustrated in FIG. 11A, first formed is the semiconductor substrate 210 which includes the base layer 211 not having the epitaxial growth layer 212.

Subsequently, as illustrated in FIG. 11B, a part of the insulation film 115 is formed within the base layer 211. For example, the insulation film 115 herein can be formed by embedding silicon oxide with use of an ALD method or the like into a hole opened in the base layer 211 by etching or the like. The insulation film 115 thus formed functions as a stopper film for an ESS (Empty Space in Silicon) described below.

Subsequently, a silicon nitride (SiN) film 216 is formed on the base layer 211 as illustrated in FIG. 11C. Then, a silicon oxide (SiO₂) film 217 is formed on the silicon nitride film 216. Then, trenches 218 for an ESS described below are formed. The trenches 218 penetrate the silicon nitride film 216 and the silicon oxide film 217, and end in the base layer 211. The trenches 218 are formed inside the stopper film (insulation film 115) within the base layer 211. Moreover, each of the trenches 218 has a smaller depth than the stopper film described above.

Subsequently, as illustrated in FIG. 11D, an ESS 219 is formed within the base layer 211. For example, the ESS 219 is formed by highly selective etching for the Si (110) surface rather than for the Si (111) surface according to introduction of flow of an alkali etchant from the trenches 218. This etching stops in the insulation film 115 described above. In such a manner, the ESS 219 extending toward the Si (110) surface is completed.

Subsequently, as illustrated in FIG. 11E, the insulation film 115 is completed by embedding silicon oxide into the trenches 218 and the ESS 219 with use of an ALD method. As a result, a pseudo FD-SOI (Fully Depleted Silicon On Insulator) structure is formed.

Subsequently, as illustrated in FIG. 11F, a flattening process is performed by CMP. In such a manner, the silicon nitride film 216 and the silicon oxide film 217 are removed.

Finally, as illustrated in FIG. 11G, the epitaxial growth layer 212 is formed on the upper side of the base layer 211, and the gate electrode 121a and the sidewall insulation film 121c constituting a double gate structure are also formed. Moreover, the drain region 121d and the source region 121e are also formed in this step. Similarly to the above, the epitaxial growth layer 212, i.e., a P-type semiconductor well region containing the channel region 212a, has an extremely low concentration also in the present embodiment. Accordingly, this semiconductor well region is a non-doped type region formed not by ion implantation but by epitaxial growth.

According to the present embodiment described above, the first amplification transistor 121 is an Fin-type MOS transistor. In this case, the channel region 212a can be formed on the Si (110) surface containing relatively fewer defects. Accordingly, electric characteristics of the first amplification transistor 121 improve.

Moreover, the insulation films 115 are formed immediately below the drain region 121d and the source region 121e in the present embodiment similarly to the other embodiments described above. Accordingly, the impurity concentration of the channel region 212a can be lowered to an extremely low concentration while a short channel effect is reduced. In such a manner, reduction of random noise is achievable even when the first amplification transistor 121 is driven in a low current region. Note that the insulation films 115 are formed immediately below not only the drain region 121d and the source region 121e, but also the channel region 212a in the present embodiment.

### (First Modification)

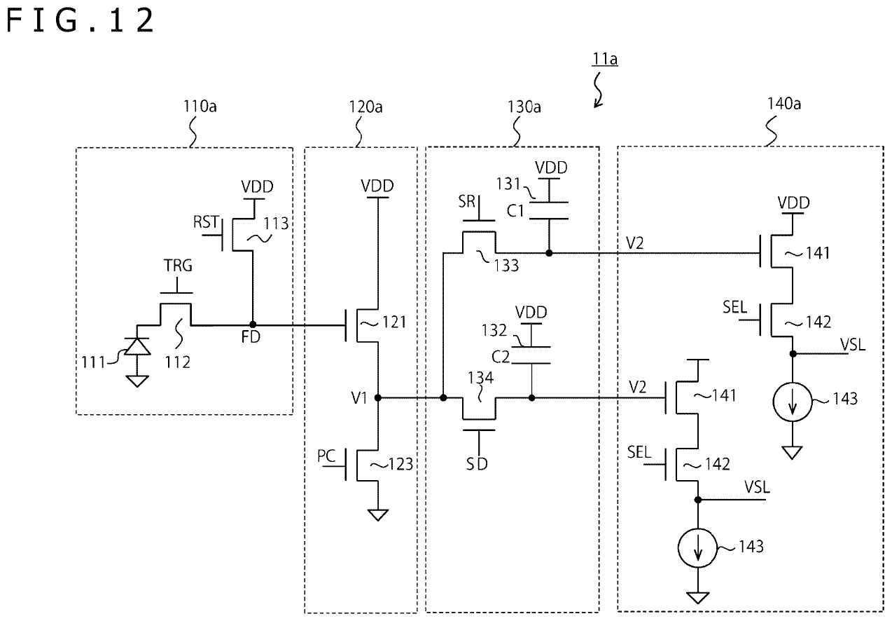

FIG. 12 is a diagram illustrating a circuit configuration of a pixel according to a first modification. Note that the circuit elements included in FIG. 12 and similar to the corresponding circuit elements of the pixel 11 according to the first embodiment described above are given identical reference signs. A pixel 11a illustrated in FIG. 12 includes a photoelectric conversion circuit 110a, a first source follower circuit 120a, a signal retention selection circuit 130a, and a second source follower circuit 140a.

The photoelectric conversion circuit 110a includes the photodiode 111, the transfer transistor 112, and the first reset transistor 113. These circuit elements are identical to the corresponding circuit elements explained in the first embodiment, and therefore will not be repeatedly touched upon in detail.

The first source follower circuit 120a includes the first amplification transistor 121 and the bias cut transistor 123. These circuit elements are also identical to the corresponding circuit elements explained in the first embodiment, and therefore will not be repeatedly touched upon in detail.

The signal retention selection circuit 130a includes the first capacitive element 131, the second capacitive element 132, the first sampling transistor 133, and the second sampling transistor 134. According to the signal retention selection circuit 130a, one end of each of the first capacitive element 131 and the second capacitive element 132 is connected to a power source line having potential of the power source voltage VDD. The other end of the first capacitive element 131 is connected to the source of the first sampling transistor 133. The other end of the second capacitive element 132 is connected to the source of the second sampling transistor 134.

The first sampling transistor 133 switches whether or not to retain a pixel signal amplified by the first source follower circuit 120a in the first capacitive element 131 in accordance with the first sampling signal SR input to the gate of the first sampling transistor 133 from the vertical drive unit 20 via the pixel drive line 80. Meanwhile, the second sampling transistor 134 switches whether or not to retain a pixel signal amplified by the first source follower circuit 120a in the second capacitive element 132 in accordance with the second sampling signal SD input to the gate of the second sampling transistor 134 from the vertical drive unit 20 via the pixel drive line 80. The drain of each of the sampling transistors is connected to a common output terminal of the first source follower circuit 120a.

The second source follower circuit 140a includes the second amplification transistor 141, the second selection transistor 142, and the current source 143. According to the second source follower circuit 140a, these circuit elements are connected to the first capacitive element 131 and the second capacitive element 132, respectively, to constitute a pair.

According to the pixel 11a configured as described above, for example, the photoelectric conversion circuit 110a, and the first amplification transistor 121 of the first source follower circuit 120a are disposed on the sensor chip 201. Moreover, the bias cut transistor 123 of the first source follower circuit 120a, the signal retention selection circuit 130a, and the second source follower circuit 140a are disposed on the logic chip 202. However, the arrangement constitutions of the sensor chip 201 and of the pixel 11a included in the sensor chip 201 are not limited to the arrangement constitutions described above.

According to the present modification, the insulation films 115 are formed immediately below the drain region 121d and the source region 121e of the first amplification transistor 121 similarly to the first embodiment described above. Accordingly, the impurity concentration of the P-type semiconductor well region (channel region 212a) between the drain region 121d and the source region 121e can be lowered while the short channel effect is reduced. In such a manner, an increase in thermal noise of the first source follower circuit 120a can be reduced even when the first amplification transistor 121 is driven by low current. Therefore, reduction of random noise is achievable along with reduction of power consumption also in the present modification.

### (Second Modification)

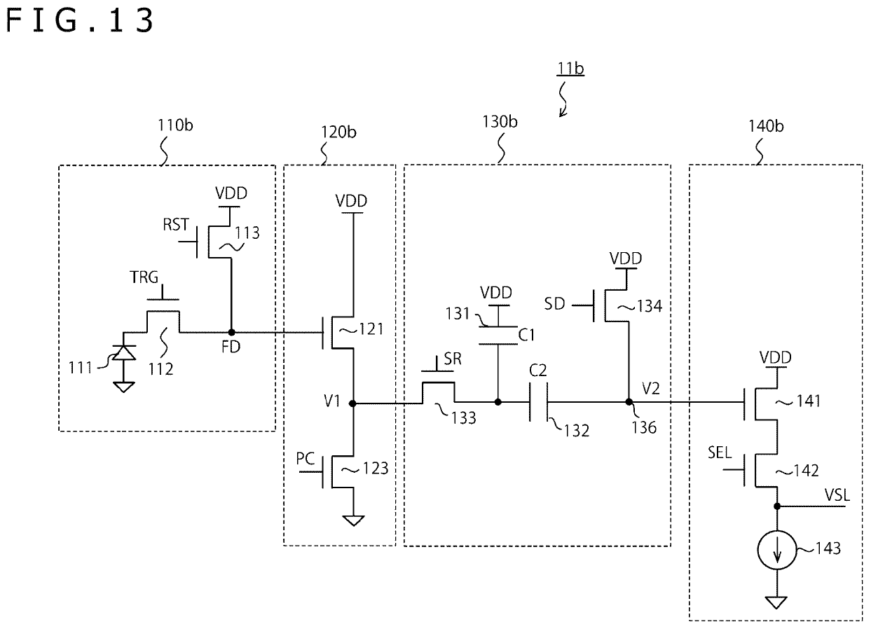

FIG. 13 is a diagram illustrating a circuit configuration of a pixel according to a second modification. Note that circuit elements included in FIG. 13 and similar to corresponding circuit elements of the pixel 11 of the first embodiment described above are given identical reference signs similarly to the above. A pixel 11b illustrated in FIG. 13 includes a photoelectric conversion circuit 110b, a first source follower circuit 120b, a signal retention selection circuit 130b, and a second source follower circuit 140b.

The photoelectric conversion circuit 110b includes the photodiode 111, the transfer transistor 112, and the first reset transistor 113. These circuit elements are identical to the corresponding circuit elements explained in the first embodiment, and therefore will not be repeatedly touched upon in detail.

The first source follower circuit 120b includes the first amplification transistor 121 and the bias cut transistor 123. These circuit elements are also identical to the corresponding circuit elements explained in the first embodiment, and therefore will not be repeatedly touched upon in detail.

The signal retention selection circuit 130b includes the first capacitive element 131, the second capacitive element 132, the first sampling transistor 133, and the second sampling transistor 134. According to the signal retention selection circuit 130b, one end of the first capacitive element 131 is connected to a power source line having potential of the power source voltage VDD. The other end of the first capacitive element 131 is connected to the source of the first sampling transistor 133 and one end of the second capacitive element 132. The other end of the second capacitive element 132 is connected to the output node 136.

The first sampling transistor 133 switches whether or not to retain a pixel signal amplified by the first source follower circuit 120a in the first capacitive element 131 and the second capacitive element 132 in accordance with the first sampling signal SR input to the gate of the first sampling transistor 133 from the vertical drive unit 20 via the pixel drive line 80. The drain of the first sampling transistor 133 is connected to the common output terminal of the first source follower circuit 120a.

The second sampling transistor 134 resets the potential of the output node 136 in accordance with the second sampling signal SD input to the gate of the second sampling transistor 134 from the vertical drive unit 20 via the pixel drive line 80. The drain of the second sampling transistor 134 is connected to the power source line described above, while the source of the second sampling transistor 134 is connected to the output node 136.

The second source follower circuit 140b includes the second amplification transistor 141, the second selection transistor 142, and the current source 143. These circuit elements are identical to the corresponding circuit elements explained in the first embodiment, and therefore will not be repeatedly touched upon in detail.

According to the pixel 11b configured as described above, for example, the photoelectric conversion circuit 110b, and the first amplification transistor 121 of the first source follower circuit 120b are disposed on the sensor chip 201. Moreover, the bias cut transistor 123 of the first source follower circuit 120b, the signal retention selection circuit 130b, and the second source follower circuit 140b are disposed on the logic chip 202. However, the arrangement constitutions of the sensor chip 201 and of the pixel 11b included in the sensor chip 201 are not limited to the arrangement constitutions described above.

According to the present modification, the insulation films 115 are formed immediately below the drain region 121d and the source region 121e of the first amplification transistor 121 similarly to the first embodiment described above. Accordingly, the impurity concentration of the P-type semiconductor well region (channel region 212a) between the drain region 121d and the source region 121e can be lowered while the short channel effect is reduced. In such a manner, an increase in thermal noise of the first source follower circuit 120b can be reduced even when the first amplification transistor 121 is driven by low current. Therefore, reduction of random noise is achievable along with reduction of power consumption also in the present modification.

### (Third Modification)

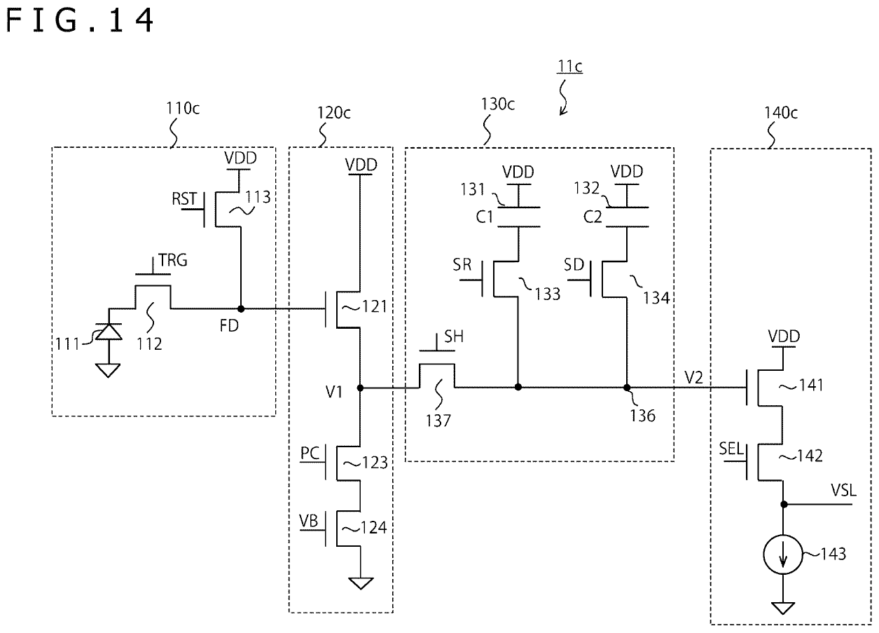

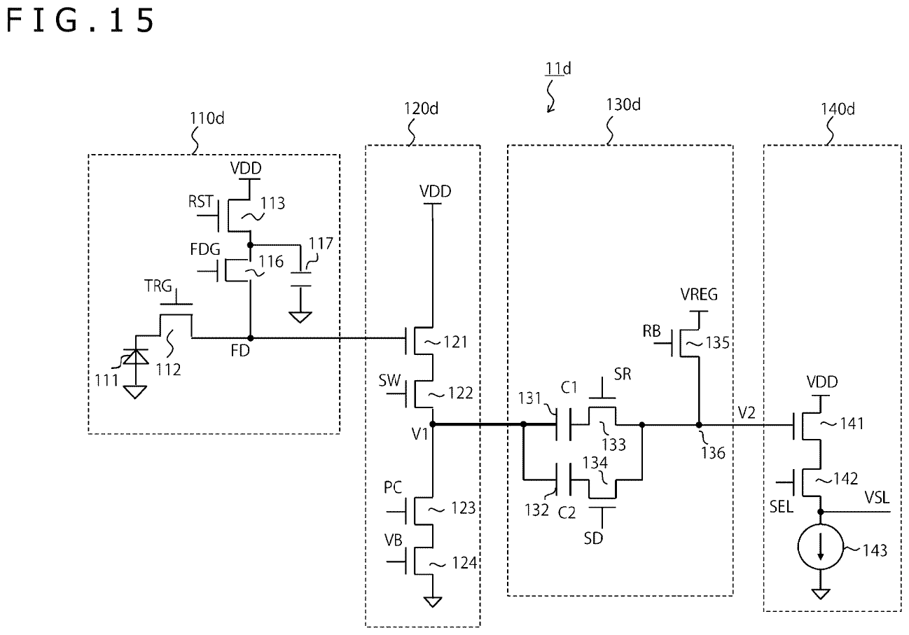

FIG. 14 is a diagram illustrating a circuit configuration of a pixel according to a third modification. Note that circuit elements included in FIG. 14 and similar to corresponding circuit elements of the pixel 11 of the first embodiment described above are given identical reference signs similarly to the above. A pixel 11c illustrated in FIG. 14 includes a photoelectric conversion circuit 110c, a first source follower circuit 120c, a signal retention selection circuit 130c, and a second source follower circuit 140c.

The photoelectric conversion circuit 110c includes the photodiode 111, the transfer transistor 112, and the first reset transistor 113. These circuit elements are identical to the corresponding circuit elements explained in the first embodiment, and therefore will not be repeatedly touched upon in detail.

The first source follower circuit 120c includes the first amplification transistor 121, the bias cut transistor 123, and the load transistor 124. These circuit elements are also identical to the corresponding circuit elements explained in the first embodiment, and therefore will not be repeatedly touched upon in detail.

The signal retention selection circuit 130c includes the first capacitive element 131, the second capacitive element 132, the first sampling transistor 133, the second sampling transistor 134, and a switching transistor 137. According to the signal retention selection circuit 130c, one end of each of the first capacitive element 131 and the second capacitive element 132 is connected to a power source line having potential of the power source voltage VDD. The other end of the first capacitive element 131 is connected to the drain of the first sampling transistor 133. The other end of the second capacitive element 132 is connected to the drain of the second sampling transistor 134.

The first sampling transistor 133 switches whether or not to output a pixel signal retained in the first capacitive element 131 to the second source follower circuit 140c in accordance with the first sampling signal SR input to the gate of the first sampling transistor 133 from the vertical drive unit 20 via the pixel drive line 80. The source of the first sampling transistor 133 is connected to a source of the switching transistor 137 and the output node 136.

The second sampling transistor 134 switches whether or not to output a pixel signal retained in the second capacitive element 132 to the second source follower circuit 140c in accordance with the second sampling signal SD input to the gate of the second sampling transistor 134 from the vertical drive unit 20 via the pixel drive line 80. The source of the second sampling transistor 134 is connected to the source of the switching transistor 137 and the output node 136.

The switching transistor 137 includes an N-channel type MOS transistor. A switching signal SH is input to a gate of the switching transistor 137 from the vertical drive unit 20 via the pixel drive line 80. When the switching transistor 137 is turned on in response to the switching signal SH, a signal amplified by the first source follower circuit 120c is retained in the first capacitive element 131 or the second capacitive element 132. The second source follower circuit 140c includes the second amplification transistor 141, the second selection transistor 142, and the current source 143. These circuit elements are identical to the corresponding circuit elements explained in the first embodiment, and therefore will not be repeatedly touched upon in detail.

According to the pixel 11c configured as described above, for example, the photoelectric conversion circuit 110c, and the first amplification transistor 121 of the first source follower circuit 120c are disposed on the sensor chip 201. Moreover, the bias cut transistor 123 and the load transistor 124 of the first source follower circuit 120c, the signal retention selection circuit 130b, and the second source follower circuit 140b are disposed on the logic chip 202. However, the arrangement constitutions of the sensor chip 201 and of the pixel 11c included in the sensor chip 201 are not limited to the arrangement constitutions described above.

According to the present modification, the insulation films 115 are formed immediately below the drain region 121d and the source region 121e of the first amplification transistor 121 similarly to the first embodiment described above. Accordingly, the impurity concentration of the P-type semiconductor well region (channel region 212a) between the drain region 121d and the source region 121e can be lowered while the short channel effect is reduced. In such a manner, an increase in thermal noise of the first source follower circuit 120c can be reduced even when the first amplification transistor 121 is driven by low current. Therefore, reduction of random noise is achievable along with reduction of power consumption also in the present modification.

### (Fourth Modification)

FIG. 15 is a diagram illustrating a circuit configuration of a pixel according to a fourth modification. Note that circuit elements included in FIG. 15 and similar to corresponding circuit elements of the pixel 11 of the first embodiment described above are given identical reference signs. A pixel 11d illustrated in FIG. 15 includes a photoelectric conversion circuit 110d, a first source follower circuit 120d, a signal retention selection circuit 130d, and a second source follower circuit 140d.

The photoelectric conversion circuit 110d includes the photodiode 111, the transfer transistor 112, the first reset transistor 113, a switching transistor 116, and a capacitive element 117. The switching transistor 116 includes an N-channel type MOS transistor, and is disposed between the first reset transistor 113 and FD. One end of the capacitive element 117 is connected to a drain of the switching transistor 116, while the other end is grounded. A drive signal FDG is input to a gate of the switching transistor 116 from the vertical drive unit 20. When the switching transistor 116 comes into an on-state in response to the drive signal FDG, charge retained in the capacitive element 117 is transferred to the FD.

Circuit configurations of the first source follower circuit 120d, the signal retention selection circuit 130d, and the second source follower circuit 140d are similar to the corresponding circuit configurations in the first embodiment, and therefore will not be repeatedly explained. According to the present modification, however, the second reset transistor 135 of the signal retention selection circuit 130d, and the second source follower circuit 140d are shared by the four pixels 11d.

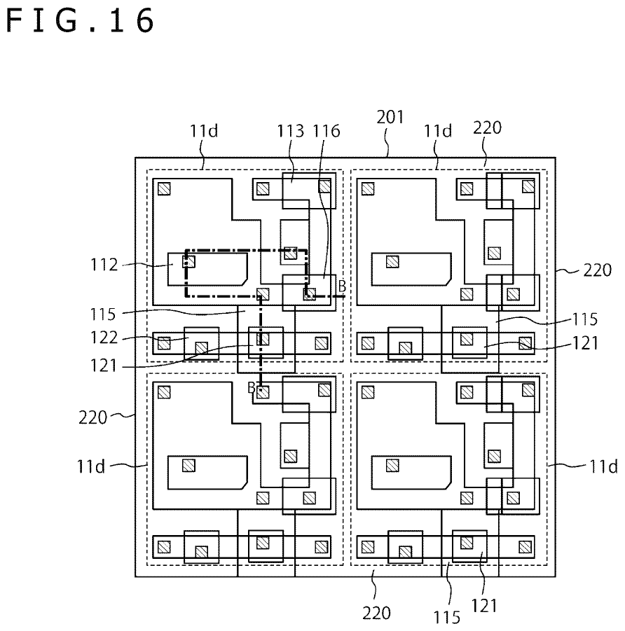

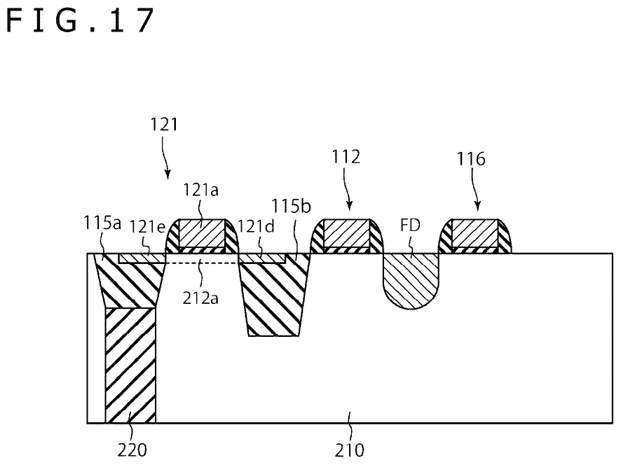

FIG. 16 is a plan diagram illustrating an example of a layout of the sensor chip 201 according to the fourth modification. Meanwhile, FIG. 17 is a cross-sectional diagram taken along a section line B-B illustrated in FIG. 16.

According to the present modification, the photoelectric conversion circuit 110d, and the first amplification transistor 121 and the first selection transistor 122 of the first source follower circuit 120d, each included in the pixel 11d, are disposed on the sensor chip 201. The remaining circuit elements of the pixel 11d are disposed on the logic chip 202. For example, the first selection transistor 122 included in the first source follower circuit 120d and disposed on the sensor chip 201 is electrically connected with the bias cut transistor 123 disposed on the logic chip 202, via wires penetrating the sensor chip 201, or pads provided on the upper surface of the sensor chip 201.

Moreover, according to the present modification, the multiple pixels 11d disposed on the sensor chip 201 are separated from each other by a separation film 220 as illustrated in FIG. 16. For example, the separation film 220 is an FFTI (Front Full Trench Isolation) type separation film formed within a trench penetrating the semiconductor substrate 210. For example, a sidewall film including silicon oxide or the like is formed within the separation film 220, and a filler including polysilicon is embedded inside this sidewall film. Note that the filler inside the FFTI is not limited to polysilicon. For example, an insulation film such as an oxide film may be a single-layer or a multi-layer film formed within the FFTI. Moreover, at least one type of a conductive material, such as a metal material and polysilicon, may be formed within the FFTI as well as the insulation film.

Furthermore, as illustrated in FIG. 17, while the separation film 220 is formed immediately below an insulation film 115a in contact with the source region 121e in the first amplification transistor 121, a separation film 200 is not formed immediately below an insulation film 115b in contact with the drain region 121d. In addition, the thickness of the insulation film 115b from the surface of the semiconductor substrate 210 is larger than the thickness of the insulation film 115a.

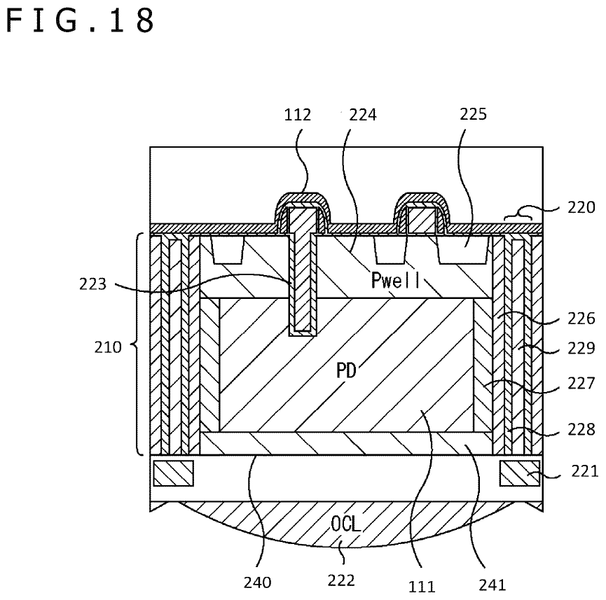

FIG. 18 is a cross-sectional diagram around the transfer transistor 112 and the first selection transistor 122 in the layout illustrated in FIG. 16. The separation film 220 formed and illustrated in FIG. 18 also penetrates the semiconductor substrate 210. A light shielding film 221 for reducing leakage of light to an adjoining pixel is formed on the rear surface side (lower side in the figure) of the separation film 220. For example, the light shielding film 221 includes a metal material such as tungsten. An OCL (on-chip lens) 222 for collecting incident light toward the photodiode 111 is formed on the rear surface side of the semiconductor substrate 210.

A trench 223 is opened on the front surface side (upper side in the figure) of the semiconductor substrate 210. The transfer transistor 112 is provided in the trench 223. Moreover, an active region (Pwell) 224 is formed in an upper part of the semiconductor substrate 210. An element separation region 225 is formed within the active region 224. Note that the transfer transistor 112 may have an excavated shape where a gate is formed inside the trench 223, or may be of a planar type where a gate is formed on the semiconductor substrate 210.

A P-type solid-phase diffusion layer 226 and an N-type solid-phase diffusion layer 227 are formed between the photodiode 111 and the separation film 220 and arranged in this order from the separation film 220 toward the photodiode 111. The photodiode 111 includes an N-type region. Photoelectric conversion is performed for a part or the whole of these N-type regions.

Moreover, a sidewall film 228 is formed on an inner wall of the separation film 220. A filler 229 is embedded inside the sidewall film 228. For example, the sidewall film 228 may include silicon oxide or silicon nitride. Meanwhile, the filler 229 can include polysilicon or doping polysilicon, for example. Note that the filler 229 is not limited to these types of polysilicon.

The P-type solid-phase diffusion layer 226 is so formed as to come into contact with a rear surface silicon interface 240. Meanwhile, the N-type solid-phase diffusion layer 227 is not in contact with the rear surface silicon interface 240.

Accordingly, a clearance is provided between the N-type solid-phase diffusion layer 227 and the rear surface silicon interface 240.

A P-type region 241 is provided between the rear surface silicon interface 240, and the photodiode 111 and the N-type solid-phase diffusion layer 227, i.e., in a region where the photodiode 111 and the like are not formed in the semiconductor substrate 210. In this case, the photodiode 111 and the N-type solid-phase diffusion layer 227 are absent in the vicinity of the rear surface silicon interface 240. Accordingly, pinning near the rear surface silicon interface 240 is not weakened, and therefore deterioration of dark characteristics caused by charge generated and flowing into the photodiode 111 can be reduced. Note that pinning of the sidewall of the separation film 220 can be strengthened by applying negative bias to the sidewall in a case where doping polysilicon is injected as the filler 229, or a case where an N-type impurity or a P-type impurity is doped after injection of polysilicon. Accordingly, dark characteristics can further improve.

According to the pixel 11d configured as above, the insulation films 115 are also formed immediately below the drain region 121d and the source region 121e of the first amplification transistor 121 similarly to the first embodiment described above. Accordingly, the impurity concentration of the P-type semiconductor well region (channel region 212a) between the drain region 121d and the source region 121e can be lowered while the short channel effect is reduced. In such a manner, an increase in thermal noise of the first source follower circuit 120c can be reduced even when the first amplification transistor 121 is driven by low current. Therefore, reduction of random noise is achievable along with reduction of power consumption also in the present modification. Particularly in the present modification, the insulation film 115b not in contact with the separation film 220 has a larger thickness than the insulation film 115a in contact with the separation film 220. Accordingly, a sufficient region of the low-concentration channel region 212a can be reliably produced.

Note that the SiGe (silicon-germanium) layer 215 may be formed immediately below the channel region 212a in the first amplification transistor 121 in the present modification similarly to the configuration explained in the second embodiment. In this case, further reduction of random noise is achievable. Moreover, the Fin-type MOS transistor explained in the third embodiment may be applied to the first amplification transistor 121.

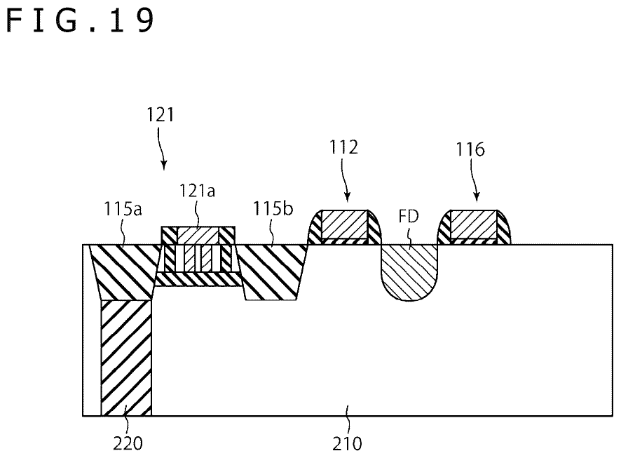

FIG. 19 is a cross-sectional diagram illustrating the first amplification transistor 121 of the fourth modification to which the Fin-type MOS transistor is applied. In a case where the Fin-type MOS transistor is applied to the first amplification transistor 121, the thickness of the insulation film 115a in contact with the separation film 220 is equivalent to the thickness of the insulation film 115b not in contact with the separation film 220.

### (Fifth Modification)

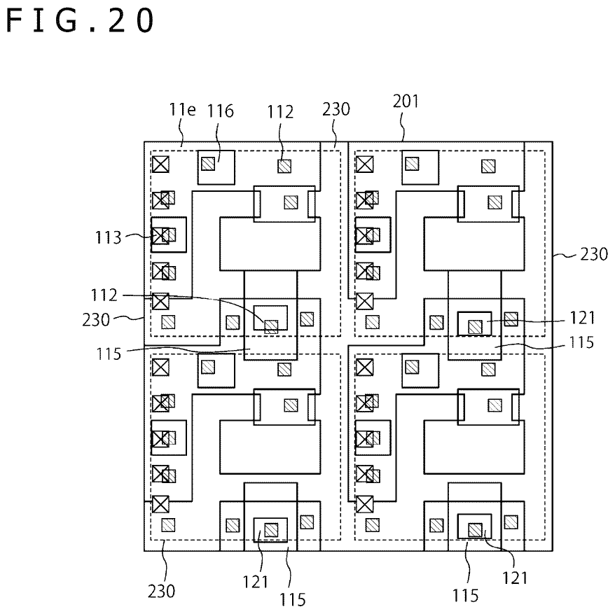

FIG. 20 is a plan diagram illustrating an example of the layout of the sensor chip 201 according to a fifth modification. The sensor chip 201 of the present modification has a size equivalent to the size of the sensor chip 201 in the fourth modification. Moreover, a pixel 11e provided on each of the sensor chip 201 and the logic chip 202 has a circuit configuration identical to the circuit configuration in the fourth modification.

Meanwhile, the multiple pixels 11e arranged on the sensor chip 201 are separated from each other by a separation layer 230 in the present modification. Moreover, the circuit elements of the respective pixels 11e are separated by the separation layer 230. For example, the separation layer 230 is formed by injecting a P-type impurity into the semiconductor substrate 210. Accordingly, the separation layer 230 is not provided below the insulation films 115 which are in contact with the drain region 121d and the source region 121e of the first amplification transistor 121.

According to the present modification, the insulation films 115 are formed immediately below the drain region 121d and the source region 121e of the first amplification transistor 121 similarly to the first embodiment described above. Accordingly, the impurity concentration of the P-type semiconductor well region (channel region 212a) between the drain region 121d and the source region 121e can be lowered while the short channel effect is reduced. In such a manner, an increase in thermal noise of the first source follower circuit 120c can be reduced even when the first amplification transistor 121 is driven by low current. Therefore, reduction of random noise is achievable along with reduction of power consumption also in the present modification.

### (Sixth Modification)

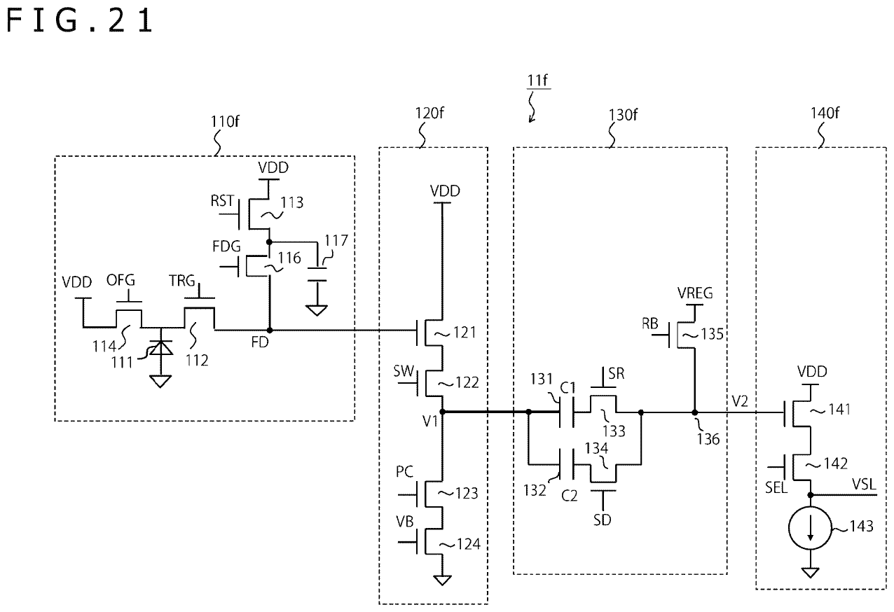

FIG. 21 is a diagram illustrating a circuit configuration of a pixel according to a sixth modification. Note that circuit elements included in FIG. 21 and similar to corresponding circuit elements of the pixel 11 of the first embodiment described above are given identical reference signs. A pixel 11f illustrated in FIG. 21 includes a photoelectric conversion circuit 110f, a first source follower circuit 120f, a signal retention selection circuit 130f, and a second source follower circuit 140f.

The photoelectric conversion circuit 110f includes the photodiode 111, the transfer transistor 112, the first reset transistor 113, the discharge transistor 114, the switching transistor 116, and the capacitive element 117. Accordingly, the photoelectric conversion circuit 110f of the present modification has a configuration which includes the discharge transistor 114 in addition to the circuit elements of the photoelectric conversion circuit 110d of the fourth modification. The discharge transistor 114 is similar to the discharge transistor 114 of the first embodiment, and therefore will not be repeatedly explained.

Moreover, the circuit configurations of the first source follower circuit 120f, the signal retention selection circuit 130f, and the second source follower circuit 140f are similar to the corresponding circuit configurations in the first embodiment, and therefore will not be repeatedly explained. According to the present modification, however, the second reset transistor 135 of the signal retention selection circuit 130f, and the second source follower circuit 140f are shared by the four pixels 11d similarly to the fourth modification and the fifth modification.

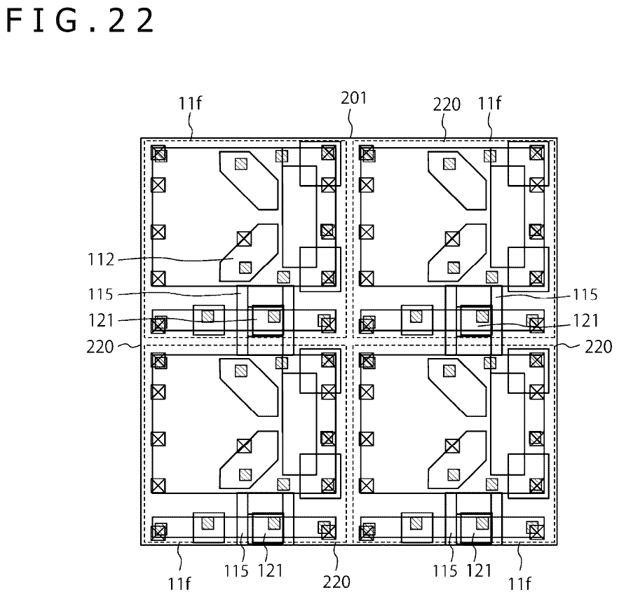

FIG. 22 is a plan diagram illustrating an example of the layout of the sensor chip 201 according to the sixth modification. The sensor chip 201 of the present modification has a larger size than the sensor chip 201 in the fourth modification. Meanwhile, the pixel 11e provided on each of the sensor chip 201 and the logic chip 202 has a circuit configuration similar to the corresponding circuit configuration in the fourth modification. Note that the discharge transistor 114 is disposed on the sensor chip 201.

Moreover, according to the present modification, the multiple pixels 11f disposed on the sensor chip 201 are separated by the separation film 220 similarly to the fourth modification. Accordingly, while the separation film 220 is formed immediately below the insulation film 115a in contact with the source region 121e in the first amplification transistor 121, the separation film 200 is not formed immediately below the insulation film 115b in contact with the drain region 121d. In addition, the thickness of the insulation film 115b from the surface of the semiconductor substrate 210 is larger than the thickness of the insulation film 115a.

According to the pixel 11f configured as above, the insulation films 115 are also formed immediately below the drain region 121d and the source region 121e of the first amplification transistor 121 similarly to the first embodiment described above. Accordingly, the impurity concentration of the P-type semiconductor well region (channel region 212a) between the drain region 121d and the source region 121e can be lowered while the short channel effect is reduced. In such a manner, an increase in thermal noise of the first source follower circuit 120c can be reduced even when the first amplification transistor 121 is driven by low current. Therefore, reduction of random noise is achievable along with reduction of power consumption also in the present modification.

Moreover, in the present modification, the insulation film 115b not in contact with the separation film 220 has a larger thickness than the insulation film 115a in contact with the separation film 220 similarly to the fourth modification described above. Accordingly, a sufficient region of the low-concentration channel region 212a can be reliably produced. Note that the SiGe (silicon-germanium) layer 215 may be formed immediately below the channel region 212a in the first amplification transistor 121 in the present modification similarly to the configuration explained in the second embodiment. In this case, further reduction of random noise is achievable. Furthermore, the first amplification transistor 121 may have either a structure which includes the SiGe (silicon-germanium) layer 215 described in the second embodiment, or a structure which includes the Fin-type MOS transistor described in the third embodiment.

### (Seventh Modification)

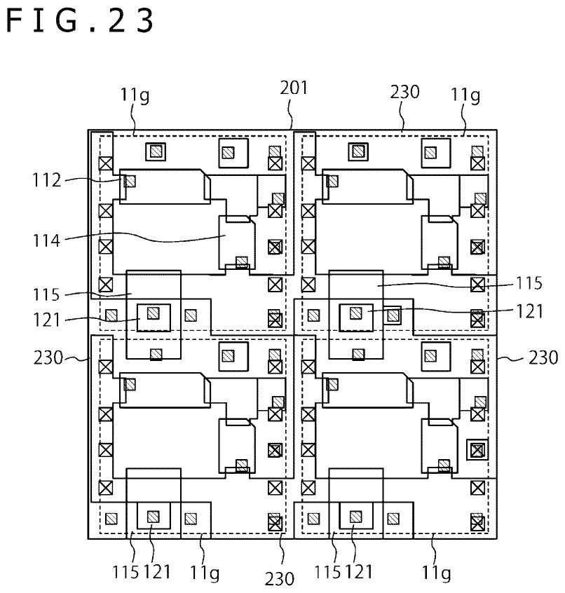

FIG. 23 is a plan diagram illustrating an example of the layout of the sensor chip 201 according to a seventh modification. The sensor chip 201 of the present modification has a size equivalent to the size of the sensor chip 201 in the sixth modification. Moreover, the pixel 11f provided on each of the sensor chip 201 and the logic chip 202 has a circuit configuration identical to the corresponding circuit configuration in the sixth modification.

Meanwhile, in the present modification, the multiple pixels 11f arranged on the sensor chip 201 are separated from each other by the separation layer 230 similarly to the fifth modification described above. Moreover, the circuit elements of the respective pixels 11f are also separated by the separation layer 230.

According to the present modification, the insulation films 115 are formed immediately below the drain region 121d and the source region 121e of the first amplification transistor 121 similarly to the first embodiment described above. Accordingly, the impurity concentration of the P-type semiconductor well region (channel region 212a) between the drain region 121d and the source region 121e can be lowered while the short channel effect is reduced. In such a manner, an increase in thermal noise of the first source follower circuit 120c can be reduced even when the first amplification transistor 121 is driven by low current. Therefore, reduction of random noise is achievable along with reduction of power consumption also in the present modification.

### Fourth Embodiment

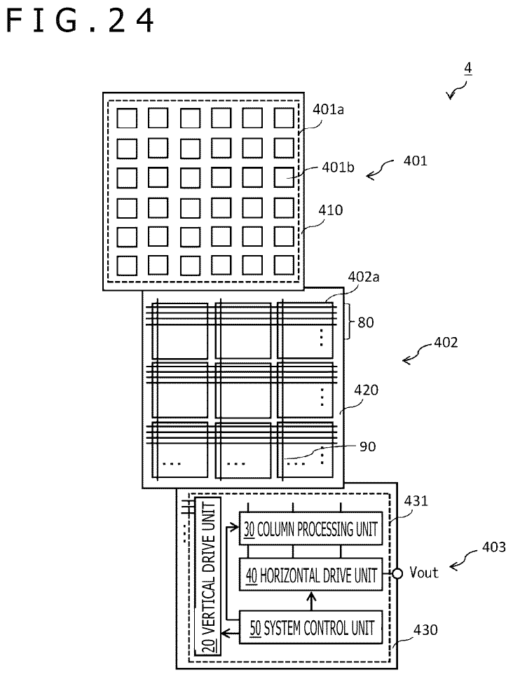

FIG. 24 is a diagram illustrating a configuration of a CMOS image sensor according to a fourth embodiment. The constituent elements similar to the corresponding constituent elements of the first embodiment described above are given identical reference signs, and will not be explained in detail. A CMOS image sensor 4 according to the present embodiment includes a first chip 401, a second chip 402, and a third chip 403. The first chip 401, the second chip 402, and the third chip 403 are laminated.

The first chip 401 includes a first pixel array unit 401a. Multiple sensor pixels 401b are two-dimensionally arranged in a matrix shape on the first pixel array unit 401a. The photodiode 111, the transfer transistor 112, the FD, the first reset transistor 113, and the discharge transistor 114 of the photoelectric conversion circuit 110 are arranged on each of the sensor pixels 401b. In addition, the first amplification transistor 121 and the first selection transistor 122 of the first source follower circuit 120 are also arranged on each of the sensor pixels 401b.

The second chip 402 includes a second pixel array unit 402a. The bias cut transistor 123 and the load transistor 124 of the first source follower circuit 120 are arranged on the second pixel array unit 402a. In addition, the signal retention selection circuit 130 and the second source follower circuit 140 are also arranged on the second pixel array unit 402a. Moreover, the pixel drive lines 80 extend in the row direction, and the vertical signal lines 90 extend in the column direction on the second pixel array unit 402a.

The third chip 403 includes a logic circuit 431. The vertical drive unit 20, the column processing unit 30, the horizontal drive unit 40, and the system control unit 50 are disposed on the logic circuit 431.

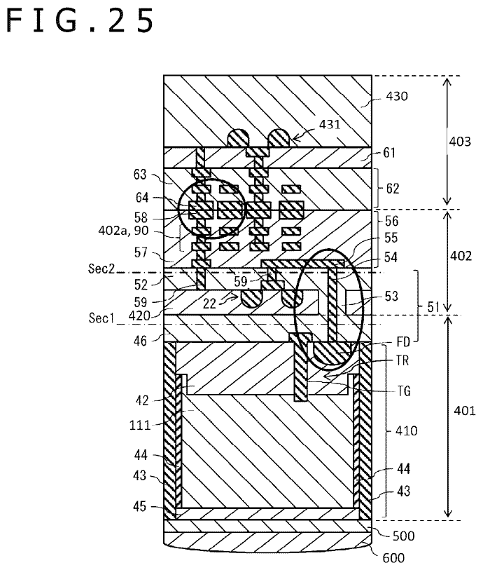

FIG. 25 is a cross-sectional diagram illustrating a part of the CMOS image sensor 4 according to the fourth embodiment taken in the vertical direction. As illustrated in FIG. 25, the first chip 401, the second chip 402, and the third chip 403 are laminated in this order on the CMOS image sensor 4. Moreover, a color filter 500 and a light receiving lens 600 are provided on the rear surface side (light entrance surface side) of the first chip 401. For example, the one color filter 500 and the one light receiving lens 600 are provided for each of the sensor pixels 401b. Accordingly, the CMOS image sensor 4 is a sensor of a back-illuminated type.

The first chip 401 includes an insulation layer 46 laminated on a first semiconductor substrate 410. The first chip 401 has the insulation layer 46 as a part of an interlayer dielectric 51. The insulation layer 46 is provided on a clearance between the first semiconductor substrate 410 and a second semiconductor substrate 420 described below.

The first semiconductor substrate 410 includes a silicon substrate. For example, the first semiconductor substrate 410 includes a p-well layer 42 on a part of and near a surface of the first semiconductor substrate 410, and the photodiode 111 of a conductivity type different from the conductivity type of the p-well layer 42 on a region other than the p-well layer 42 (a region deeper than the p-well layer 42). The p-well layer 42 includes a p-type semiconductor region. The photodiode 111 includes a semiconductor region of a conductivity type (specifically, n-type) different from the conductivity type of the p-well layer 42. The first semiconductor substrate 410 includes FD formed within the p-well layer 42 as a semiconductor region of a conductivity type (specifically, n-type) different from the conductivity type of the p-well layer 42.

The first chip 401 includes the transfer transistor 112 and the FD on a portion on the front surface side of the first semiconductor substrate 410 (on the side opposite to the light entrance surface side, the second chip 402 side). The first chip 401 includes an element separation portion 43 which separates the respective sensor pixels 401b.

The element separation portion 43 is so formed as to extend in the normal direction of the first semiconductor substrate 410 (the direction perpendicular to the surface of the first semiconductor substrate 410). The element separation portion 43 is provided between the two adjoining sensor pixels 401b. The element separation portion 43 electrically separates the adjoining sensor pixels 401b. For example, the element separation portion 43 includes silicon oxide. For example, the element separation portion 43 penetrates the first semiconductor substrate 410.

For example, the first chip 401 further includes a p-well layer 44 in contact with a surface which is a side surface of the element separation portion 43 and is located near the photodiode 111. The p-well layer 44 includes a semiconductor region of a conductivity type (specifically, p-type) different from the conductivity type of the photodiode 111.

For example, the first chip 401 further includes a fixed charge film 45 in contact with the rear surface of the first semiconductor substrate 410. The fixed charge film 45 is negatively charged to reduce dark current generated by an interface state on the light receiving surface side of the first semiconductor substrate 410. For example, the fixed charge film 45 is constituted by an insulation film having negative fixed charge. Examples of the material for this insulation film include hafnium oxide, zircon oxide, aluminum oxide, titanium oxide, and tantalum oxide. A hole accumulation layer is formed on an interface on the light receiving surface side of the first semiconductor substrate 410 by an electric field induced by the fixed charge film 45. This hole accumulation layer reduces generation of electrons from the interface.

The color filter 500 is provided on the rear surface side of the first semiconductor substrate 410. For example, the color filter 500 is provided in contact with the fixed charge film 45, and disposed at a position facing the sensor pixel 401b via the fixed charge film 45.

For example, the light receiving lens 600 is provided in contact with the color filter 500 and is disposed at a position facing the sensor pixel 401b via the color filter 500 and the fixed charge film 45.

The second chip 402 includes an insulation layer 52 laminated on the second semiconductor substrate 420. The second chip 402 has the insulation layer 52 as a part of an interlayer dielectric 51. The insulation layer 52 is provided at a clearance between the second semiconductor substrate 420 and a third semiconductor substrate 430. The second semiconductor substrate 420 is constituted by a silicon substrate. The second chip 402 includes the second pixel array unit 402a provided on a portion on the front surface side of the second semiconductor substrate 420 (third chip 403 side). The second chip 402 is affixed to the first chip 401 in such a manner that the rear surface of the second semiconductor substrate 420 faces the front surface side of the first semiconductor substrate 410. Accordingly, the second chip 402 is affixed to the first chip 401 in a face-to-back manner. The second chip 402 further includes an insulation layer 53 formed in the same layer as the layer of the second semiconductor substrate 420 and penetrating the second semiconductor substrate 420. The second chip 402 has the insulation layer 53 as a part of the interlayer dielectric 51. The insulation layer 53 is so provided as to cover a side surface of a through wire 54 described below.

A laminate having the first chip 401 and the second chip 402 includes the interlayer dielectric 51 and the through wire 54 provided within the interlayer dielectric 51. The laminate described above includes the one through wire 54 for each of the sensor pixels 401b. The through wire 54 extends in the normal direction of the second semiconductor substrate 420, and penetrates a portion containing the insulation layer 53 in the interlayer dielectric 51. The first chip 401 and the second chip 402 are electrically connected with each other via the through wire 54. Specifically, the through wire 54 is electrically connected with FD and a connection wire 55 described below.

For example, the second chip 402 includes multiple connection portions 59 provided within the insulation layer 52 and electrically connected with the second pixel array unit 402a and the second semiconductor substrate 420. For example, the second chip 402 further includes a wiring layer 56 on the insulation layer 52. For example, the wiring layer 56 includes an insulation layer 57, the multiple pixel drive lines 80, and the multiple vertical signal lines 90 provided within the insulation layer 57. For example, the wiring layer 56 further includes the multiple connection wires 55 within the insulation layer 57 in such a manner that the one connection wire 55 is provided for each set of the four sensor pixels 401b.

Each of the connection wires 55 electrically connects the respective through wires 54 electrically connected with FD included in the four sensor pixels 401b sharing the second pixel array unit 402a. The total number of the through wires 54 herein is larger than the total number of the sensor pixels 401b included in the first chip 401, specifically, twice the total number of the sensor pixels 401b included in the first chip 401. Moreover, the total number of the through wires 54 is larger than the total number of the sensor pixels 401b included in the first chip 401, specifically, three times the total number of the sensor pixels 401b included in the first chip 401.

For example, the wiring layer 56 further includes multiple pad electrodes 58 within the insulation layer 57. For example, each of the pad electrodes 58 includes metal such as Cu (copper) and Al (aluminum). The respective pad electrodes 58 are exposed on the surface of the wiring layer 56. The respective pad electrodes 58 are employed for electric connection between the second chip 402 and the third chip 403 and for affixation between the second chip 402 and the third chip 403.

For example, the multiple pad electrodes 58 are formed such that the one pad electrode 58 is provided for each of the pixel drive lines 80 and each of the vertical signal lines 90. Note herein that the total number of the pad electrodes 58 is smaller than the total number of the sensor pixels 401b included in the first chip 401.

For example, the third chip 403 includes an interlayer dielectric 61 laminated on the third semiconductor substrate 430. The third semiconductor substrate 430 includes a silicon substrate. The third chip 403 includes the logic circuit 431 provided at a portion on the front surface side of the third semiconductor substrate 430.

For example, the third chip 403 further includes a wiring layer 62 on the interlayer dielectric 61. For example, the wiring layer 62 includes an insulation layer 63, and multiple pad electrodes 64 provided within the insulation layer 63. The multiple pad electrodes 64 are electrically connected with the logic circuit 431. For example, the respective pad electrodes 64 include Cu (copper). The respective pad electrodes 64 are exposed on the surface of the wiring layer 62. The respective pad electrodes 64 are employed for electric connection between the second chip 402 and the third chip 403 and for affixation between the second chip 402 and the third chip 403. In addition, it is not required that the pad electrodes 64 be constituted by multiple pad electrodes. Only one pad electrode can be provided to achieve electric connection with the logic circuit 431.

The second chip 402 and the third chip 403 are electrically connected with each other by junction between the pad electrodes 58 and 64. Specifically, the gate of the transfer transistor 112 is electrically connected with the logic circuit 431 via the through wire 54 and the pad electrodes 58 and 64. The third chip 403 is affixed to the second chip 402 in such a manner that the front surface of the third semiconductor substrate 430 faces the front surface side of the second semiconductor substrate 420. Accordingly, the third chip 403 is affixed to the second chip 402 in a face-to-face manner.

According to the CMOS image sensor 4 of the present embodiment configured as described above, the first amplification transistor 121 is provided within the second pixel array unit 402a of the second chip 402. The insulation films 115 are formed immediately below the drain region 121d and the source region 121e of the first amplification transistor 121 within the second pixel array unit 402a similarly to the first embodiment described above. Accordingly, the impurity concentration of the P-type semiconductor well region (channel region 212a) between the drain region 121d and the source region 121e can be lowered while the short channel effect is reduced. In such a manner, an increase in thermal noise of the first source follower circuit 120c can be reduced even when the first amplification transistor 121 is driven by low current. Therefore, reduction of random noise is achievable along with reduction of power consumption also in the present embodiment.

Note that the junction mode between the second chip 402 and the third chip employed in the present embodiment is Cu—Cu bonding which is junction between pad electrodes and that the junction mode between the first chip 401 and the second chip 402 is TSV (Through-Silicon Via) junction which is junction by through wires. However, the second chip 402 and the third chip 403 may be joined by TSV junction, and the first chip 401 and the second chip can be joined by Cu—Cu bonding.

### Fifth Embodiment

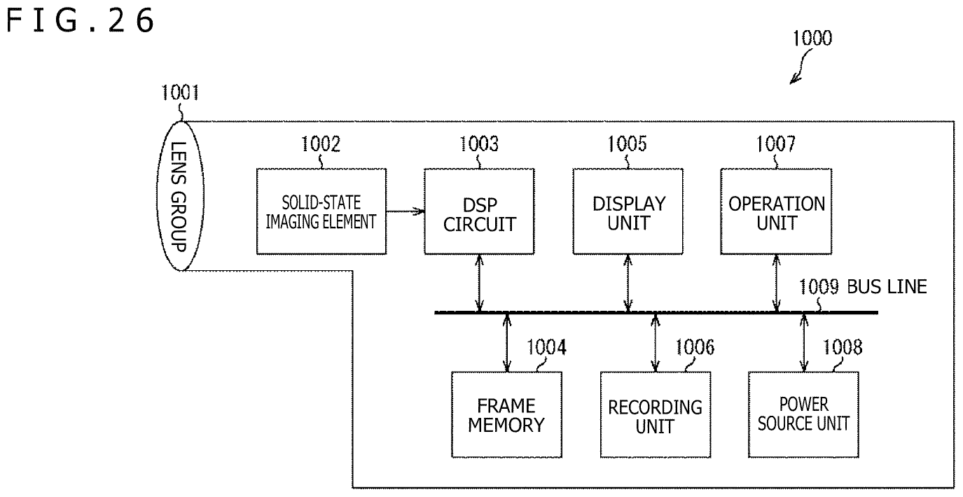

FIG. 26 is a block diagram illustrating a configuration example of an electronic apparatus according to a fifth embodiment.

An electronic apparatus 1000 illustrated in FIG. 26 is a video camera, a digital still camera, or the like. The electronic apparatus 1000 includes a lens group 1001, a solid-state CMOS image sensor 4002, a DSP circuit 1003, a frame memory 1004, a display unit 1005, a recording unit 1006, an operation unit 1007, and a power source unit 1008. The DSP circuit 1003, the frame memory 1004, the display unit 1005, the recording unit 1006, the operation unit 1007, and the power source unit 1008 are connected to one another via a bus line 1009.

The lens group 1001 introduces incident light (image light) coming from a subject, and forms an image of the light on an imaging surface of the solid-state CMOS image sensor 4002. The solid-state CMOS image sensor 4002 is any one of the CMOS image sensors according to the respective embodiments described above. The solid-state CMOS image sensor 4002 converts a light amount of the incident light of the image formed on the imaging surface by the lens group 1001 into an electric signal for each pixel, and supplies the electric signal to the DSP circuit 1003 as a pixel signal.

The DSP circuit 1003 performs predetermined image processing for the pixel signal supplied from the solid-state CMOS image sensor 4002, supplies the processed image signal to the frame memory 1004 for each frame, and temporarily stores the supplied signal in the frame memory 1004.

For example, the display unit 1005 includes a panel-type display device, such as a liquid crystal panel and an organic EL (Electro Luminescence) panel, and displays an image on the basis of the pixel signal for each frame temporarily stored in the frame memory 1004.

The recording unit 1006 includes a DVD (Digital Versatile Disk), a flash memory, or the like, and is configured to read the pixel signal temporarily stored in the frame memory 1004 for each frame, and record the read pixel signal.

The operation unit 1007 issues operation commands associated with various functions of the electronic apparatus 1000 according to an operation performed by a user. The power source unit 1008 supplies power to the DSP circuit 1003, the frame memory 1004, the display unit 1005, the recording unit 1006, and the operation unit 1007.

The electronic apparatus to which the present technology is applied is only required to be such a device which includes a CMOS image sensor as an image introduction unit (photoelectric conversion unit). Examples of the electronic apparatus include a portable terminal device having an imaging function, a copying machine including a CMOS image sensor as an image reading unit, and the like as well as the electronic apparatus 1000.

The electronic apparatus 1000 according to the present embodiment described above includes any one of the CMOS image sensors of the respective present embodiments described above as the solid-state CMOS image sensor 4002. In this case, the solid-state CMOS image sensor 4002 has a low random noise function. Accordingly, imaging performance improves.

### Examples of Application to Moving Body

The technology according to the present disclosure (present technology) is applicable to various products. For example, the technology according to the present disclosure may be implemented as a device mounted on a moving body of any type selected from cars, electric cars, hybrid electric cars, motorcycles, bicycles, personal mobilities, airplanes, drones, vessels, robots, and others.

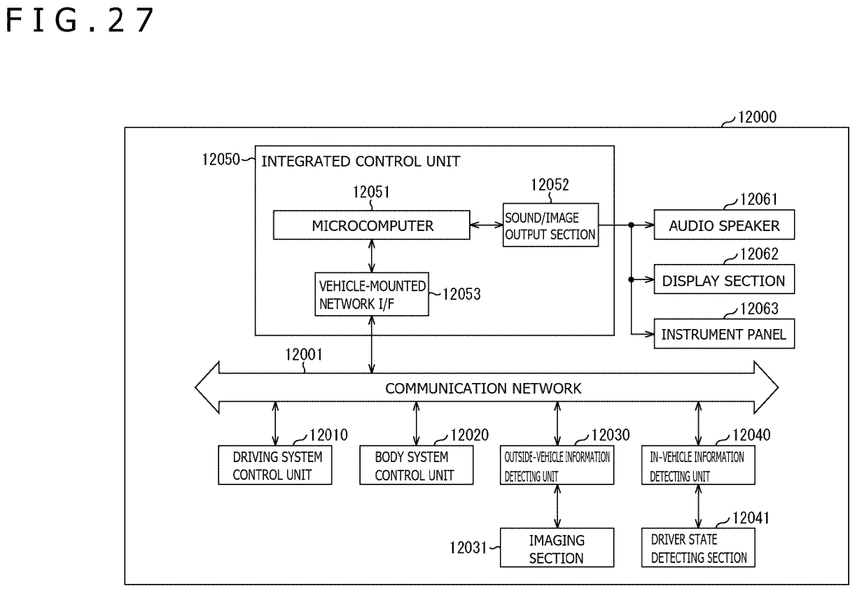

FIG. 27 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 27, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 27, an audio speaker 12061, a display section 12062, and an instrument panel 12063 are illustrated as the output device. The display section 12062 may, for example, include at least one of an on-board display and a head-up display.

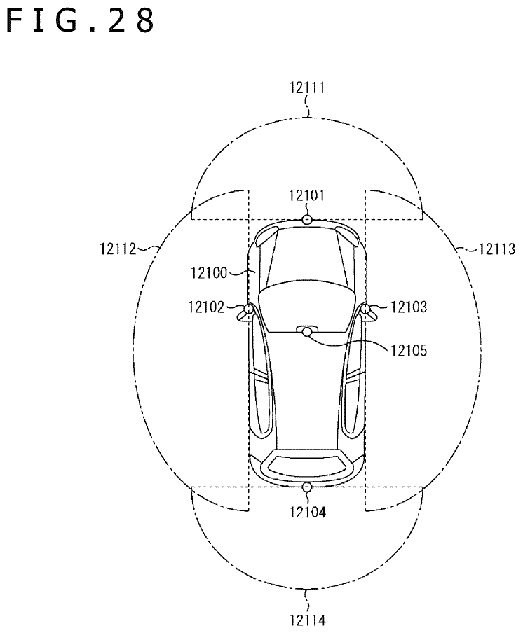

FIG. 28 is a diagram depicting an example of the installation position of the imaging section 12031.

In FIG. 28, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 28 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

One example of the vehicle control system to which the technology according to the present disclosure is applicable has been described above. For example, the technology according to the present disclosure is applicable to the imaging section 12031 included in the configurations described above. Specifically, the CMOS image sensor described above may be incorporated in the imaging section 12031. Accurate distance information is acquirable in an imaging environment containing reduced random noise by applying the technology of the present disclosure to the imaging section 12031. As a result, functionality and safety of the vehicle 12100 improve.

(1)

A light receiving element including:
a photoelectric conversion circuit that photoelectrically converts incident light into a pixel signal and outputs the pixel signal; and
a source follower circuit that includes an amplification transistor that amplifies the pixel signal, in which
an insulation film is formed immediately below each of a drain region and a source region of the amplification transistor.
   (2)

The light receiving element according to (1), in which an impurity concentration of a semiconductor well region formed between the drain region and the source region is a concentration at which depletion reaches a depth equivalent to each of lower ends of the drain region and the source region or a position deeper than the lower ends during driving of the amplification transistor.

(3)

The light receiving element according to (2), in which the impurity concentration is ten times or lower than 4e17 (cm⁻³).

(4)

The light receiving element according to (2) or (3), in which the semiconductor well region is an epitaxial growth layer of silicon.

(5)

The light receiving element according to any one of (2) to (4), in which the semiconductor well region includes a silicon-germanium layer immediately below a channel region formed between the drain region and the source region during driving of the amplification transistor.

(6)

The light receiving element according to any one of (1) to (5), in which the insulation film has a thickness larger than at least a depth of a depletion layer formed during driving of the amplification transistor.

(7)

The light receiving element according to (6), in which the insulation film has a thickness equal to or smaller than 10% of a thickness of a semiconductor substrate constituting the amplification transistor.

(8)

The light receiving element according to any one of (1) to (7), in which the insulation film surrounds the amplification transistor.

(9)

The light receiving element according to any one of (1) to (8), in which a part of each of the drain region and the source region is a polysilicon film.

(10)

The light receiving element according to (1), in which the insulation film is also formed immediately below a channel region formed between the drain region and the source region during driving of the amplification transistor.

(11)

The light receiving element according to (10), in which the channel region is formed on an Si (110) surface.

(12)

The light receiving element according to (11), in which the amplification transistor is a Fin-type MOS transistor.

(13)

The light receiving element according to any one of (1) to (12), in which the amplification transistor is disposed on a semiconductor substrate identical to a semiconductor substrate of the photoelectric conversion circuit.

(14)

The light receiving element according to any one of (1) to (12), in which the amplification transistor is disposed on a semiconductor substrate different from a semiconductor substrate of the photoelectric conversion circuit.

(15)

An electronic apparatus including:
a light receiving element including a photoelectric conversion circuit that photoelectrically converts incident light into a pixel signal and outputs the pixel signal, and a source follower circuit that includes an amplification transistor that amplifies the pixel signal, in which
an insulation film is formed immediately below each of a drain region and a source region of the amplifier transistor.

Modes of the present disclosure are not limited to the individual embodiments described above, and include various modifications that can occur to those skilled in the art. In addition, advantageous effects of the present disclosure are not limited to the specific effects described above. Accordingly, various additions, modifications, and partial deletions can be made without departing from the scope of the conceptual ideas and the spirits of the present disclosure derivable from the details and the equivalents thereof defined in the claims.

### REFERENCE SIGNS LIST

1: CMOS image sensor
110: Photoelectric conversion circuit
115: Insulation film
120: First source follower circuit
121: First amplification transistor
121d: Drain region
121e: Source region
212: Epitaxial growth layer
212a: Channel region
214: Polysilicon film
215: SiGe layer
1000: Electronic apparatus

1. A light receiving element comprising:
a photoelectric conversion circuit that photoelectrically converts incident light into a pixel signal and outputs the pixel signal; and
a source follower circuit that includes an amplification transistor that amplifies the pixel signal, wherein
an insulation film is formed immediately below each of a drain region and a source region of the amplification transistor.

2. The light receiving element according to claim 1, wherein an impurity concentration of a semiconductor well region formed between the drain region and the source region is a concentration at which depletion reaches a depth equivalent to each of lower ends of the drain region and the source region or a position deeper than the lower ends during driving of the amplification transistor.

3. The light receiving element according to claim 2, wherein the impurity concentration is ten times or lower than 4e¹⁷ (cm⁻³).

4. The light receiving element according to claim 2, wherein the semiconductor well region is an epitaxial growth layer of silicon.

5. The light receiving element according to claim 2, wherein the semiconductor well region includes a silicon-germanium layer immediately below a channel region formed between the drain region and the source region during driving of the amplification transistor.

6. The light receiving element according to claim 1, wherein the insulation film has a thickness larger than at least a depth of a depletion layer formed during driving of the amplification transistor.

7. The light receiving element according to claim 6, wherein the insulation film has a thickness equal to or smaller than 10% of a thickness of a semiconductor substrate constituting the amplification transistor.

8. The light receiving element according to claim 1, wherein the insulation film surrounds the amplification transistor.

9. The light receiving element according to claim 1, wherein a part of each of the drain region and the source region is a polysilicon film.

10. The light receiving element according to claim 1, wherein the insulation film is also formed immediately below a channel region formed between the drain region and the source region during driving of the amplification transistor.

11. The light receiving element according to claim 10, wherein the channel region is formed on an Si (110) surface.

12. The light receiving element according to claim 11, wherein the amplification transistor is a Fin-type MOS transistor.

13. The light receiving element according to claim 1, wherein the amplification transistor is disposed on a semiconductor substrate identical to a semiconductor substrate of the photoelectric conversion circuit.

14. The light receiving element according to claim 1, wherein the amplification transistor is disposed on a semiconductor substrate different from a semiconductor substrate of the photoelectric conversion circuit.

15. An electronic apparatus comprising:
a light receiving element including a photoelectric conversion circuit that photoelectrically converts incident light into a pixel signal and outputs the pixel signal, and a source follower circuit that includes an amplification transistor that amplifies the pixel signal, wherein
an insulation film is formed immediately below each of a drain region and a source region of the amplifier transistor.
